(19) United States
(12) Patent Application Publication
(10) Pub. No.: US 2022/0213267 A1
(43) Pub. Date: Jul. 7, 2022

(54) EXTREME HIGH TEMPERATURE STABLE ADHESIVES AND COATINGS

(71) Applicant: Designer Molecules, Inc., San Diego, CA (US)

(72) Inventors: Farhad G Mizori, San Diego, CA (US); Eunsook Chae Barber, San Diego, CA (US)

(21) Appl. No.: 17/604,985

(22) PCT Filed: Apr. 17, 2020
(86) PCT No.: PCT/US2020/028868

§ 371 Date: Oct. 19, 2021

Related U.S. Application Data
(60) Provisional application No. 62/836,570, filed on Apr. 19, 2019.

(51) Int. Cl. C08G 73/10; C08J 5/24

(52) U.S. Cl. CPC C08G 73/1017; C08G 73/1014; C08J 2479/08; C08J 5/24; C08G 73/1071

(57) ABSTRACT

The present invention provides curable polyimides with low color that are resistant to long term thermo-oxidative degradation. These materials, which include polyimides that are fully aromatic, are synthesized in anisole and are contemplated for use in high temperature applications such as in the aerospace industry and for use as encapsulants for light emitting diodes that will be exposed to high temperatures.

### RELATED APPLICATIONS

This application claims the benefit of priority under 35 USC § 119 of U.S. Provisional Patent Application Ser. No. 62/836,570 (filed Apr. 19, 2019), the entire disclosure of which is incorporated herein by reference.

### FIELD OF INVENTION

The present invention relates to protective barriers or protective coatings for light emitting diodes (LED's) or organic light-emitting diodes (OLED's). The present invention is directed to curable thermoplastic polyimides that are resistant to thermo-oxidative degradation. The curable polyimides can serve as a protective coating over the outer surface of an LED or OLED that is mounted to a substrate, such as a circuit board. The invention compounds can also be used as adhesives and coatings for other applications requiring long-term use at temperatures in excess of 200° C.

### BACKGROUND OF INVENTION

A variety of solid-state lighting technologies utilize electronic light sources, such as light-emitting diodes (LEDs) and organic light-emitting diode (OLEDs). LEDs and OLEDs have many advantages over traditional light sources including smaller size, longer lifetime, lower energy consumption, and higher efficiency as measured by its light output per unit power input. The average length of life of a typical LED is estimated to range from 50,000 hours to 100,000 hours.

LEDs are solid-state devices that convert electric energy to light and generally include an active region of semiconductor material sandwiched between two oppositely doped layers of semiconductor material. When a bias is applied across the doped layers, holes and electrons are injected into the active region where they recombine to generate light. Light is emitted from the active layer and from all surfaces of the LED.

High power light-emitting diodes can use 350 milliwatts or more in a single LED. Most of the electricity in an LED becomes heat rather than light (about 70% heat and 30% light). If this heat is not removed, the LEDs run at high temperatures, which not only lowers their efficiency, but also makes the LED less reliable. Thus, thermal management of high-power LEDs is a crucial area of research and development. It is necessary to limit the junction temperature to a value that will guarantee the desired LED lifetime.

LED's and OLED's are protected from the surrounding environment by a protective coating. This coating must be hydrophobic, optically clear, typically colorless, unaffected by high temperature and transparent to light following exposure to heat and ultraviolet radiation.

Aliphatic, low modulus maleimide-terminated polyimides synthesized by Designer Molecules, Inc, show high temperature stability based on dynamic TGA in air. These materials are heat stable for very short duration (a few seconds), for example, during solder reflow conditions at temperatures of about 260° C. However, maleimide-terminated polyimides have been found to undergo thermo-oxidative degradation at a very high rate when exposed to temperatures greater than 180° C. Even short duration exposure to temperatures greater than 200° C. cause these polyimides to lose flexibility; prolonged exposure causes the material to turn black and very brittle, both indications of thermo-oxidative degradation. Adding certain antioxidants can avert some of problems associated with thermo-oxidative degradation. However, large amounts of antioxidant are required to improve thermal aging, and undesirable antioxidant leaching can occur.

Fully aromatic curable polyimides have also been synthesized and tested under similar conditions. In long-term aging studies at 250° C., aromatic polyimides do not lose substantial amounts of weight, yet still turn very dark over time.

Thus, there remains a continuing need for heat-stable materials that neither lose weight nor darken at high temperatures (e.g., ≥250° C.) during exposures commensurate in time with the lifespan of LED and OLED lighting.

### SUMMARY OF THE INVENTION

The present invention provides thermo-oxidation-resistant compounds, compositions and coatings comprising at least one compound having a structure according to Formula I:

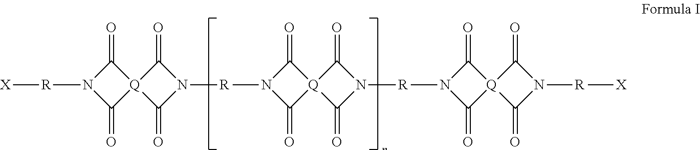

where R is selected from the group consisting of substituted or unsubstituted aromatic, heteroaromatic, or fluorinated aromatic; Q is selected from the group consisting of substituted or unsubstituted aromatic, heteroaromatic, or fluorinated aromatic; X is a curable moiety; and n is 0 or an integer having the value from 1-100; with the proviso that both R and Q contain no primary, secondary, tertiary or benzylic hydrogen.

In certain embodiments, each R and Q is independently selected from the group consisting of substituted or unsubstituted aromatic, heteroaromatic, or fluorinated aromatic, with the proviso neither R nor Q contain primary, secondary, tertiary or benzylic hydrogen atoms. In other embodiments, X is selected from the group consisting of maleimide, citraconimide, itaconimide, and benzoxazine.

Exemplary compounds of the invention include:

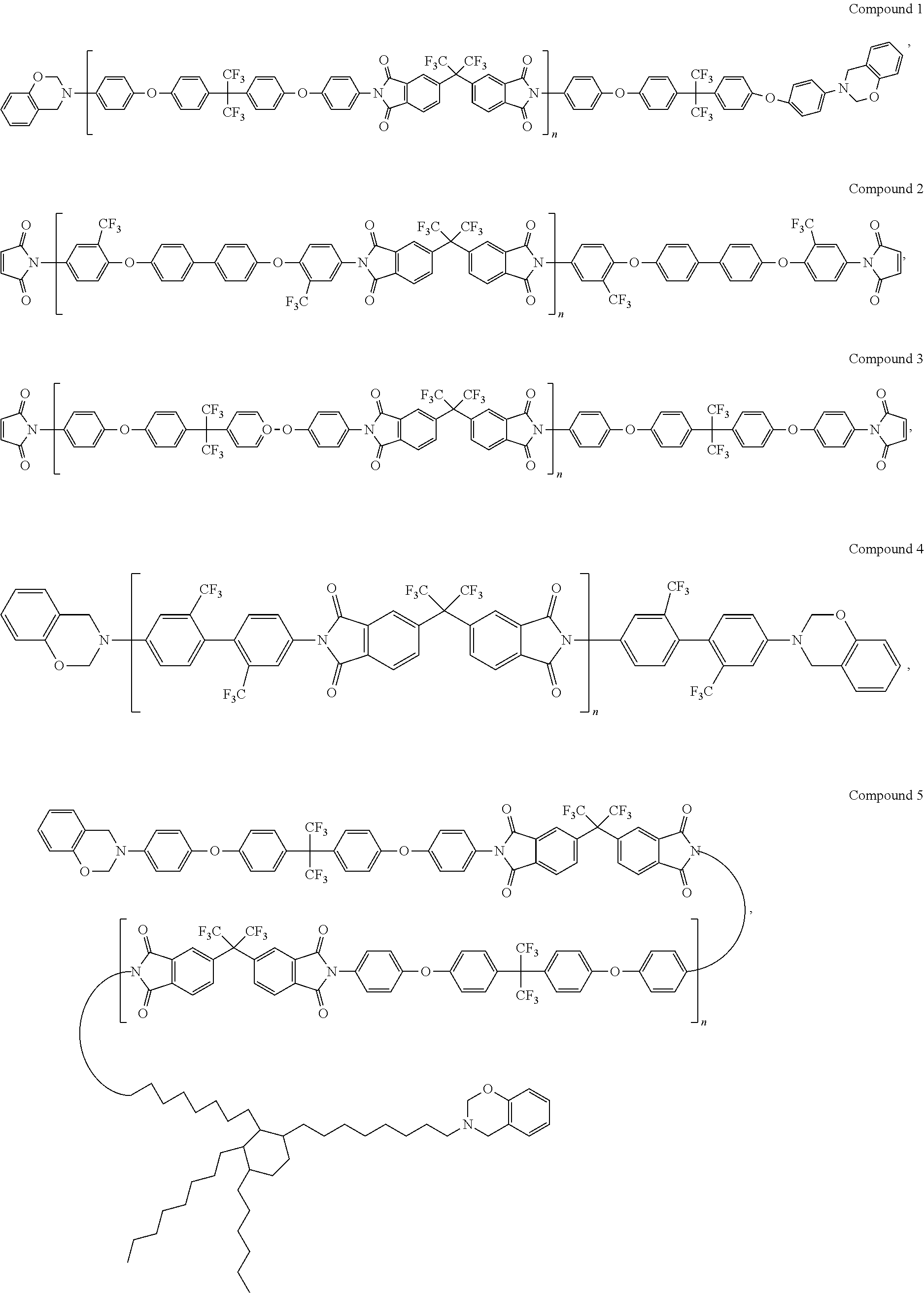

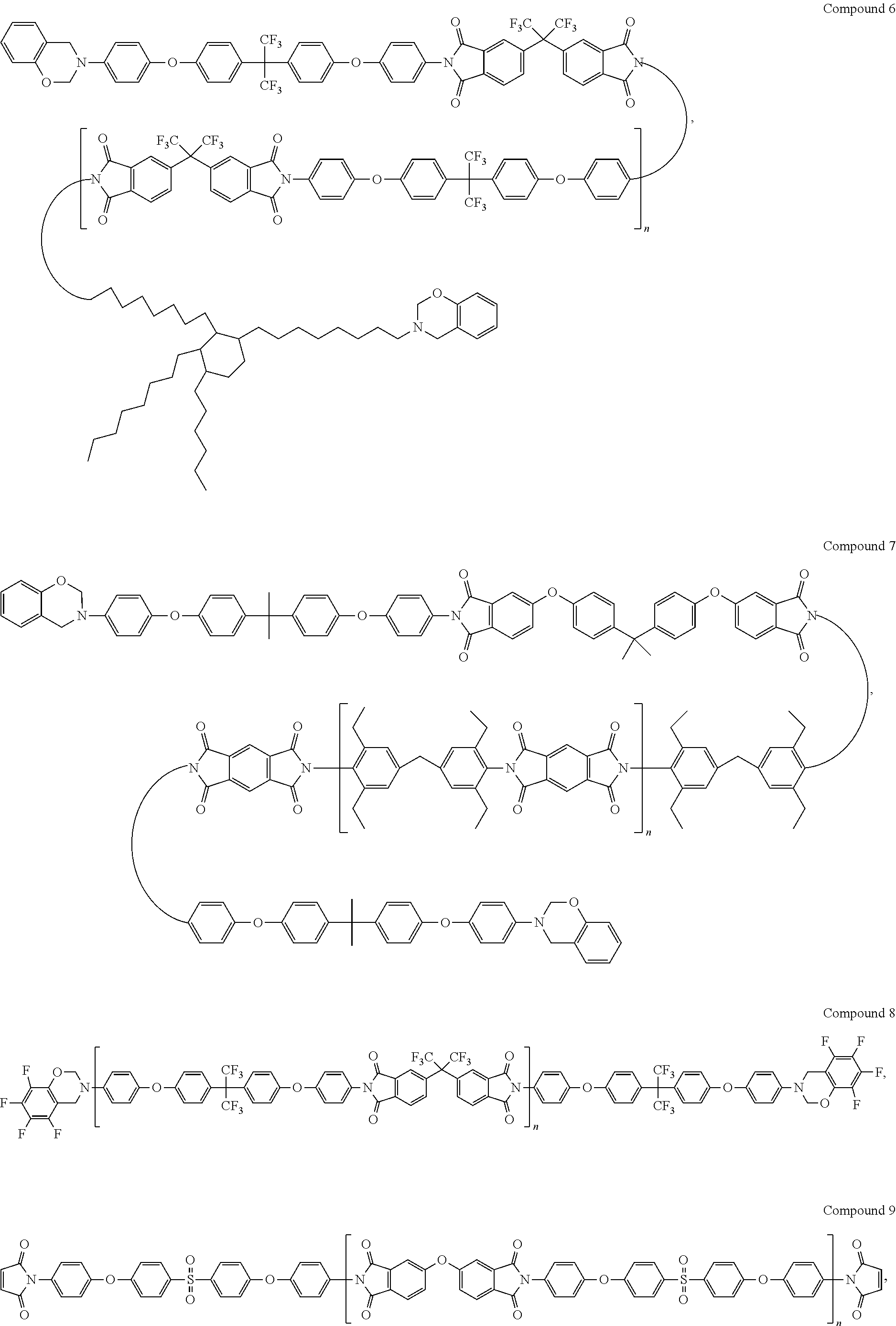

where n is 1-100,

and combinations thereof.

In some aspects of the invention, n is 20-100.

The thermo-oxidation-resistant compositions can include thermally-stable filler, coupling agent, co-reactant, or combinations thereof. Such fillers, coupling agent, co-reactant, or combination thereof are typically stable to at least at 250° C. or for at least about 400° for at least 1,000 hours. In some aspects, the thermally stable filler, coupling agent, co-reactant, or combination thereof, contains no primary, secondary, tertiary or benzylic hydrogen atoms.

The thermally stable coupling agents can be, e.g., silane coupling agents, titanium coupling agents, zirconium coupling agents and combinations thereof.

The thermally stable filler can be, e.g., silica, perfluorinated hydrocarbons, graphite, carbon black, carbon nanotubes, POSS, boron nitride, silver, and copper alloys and combinations thereof.

The thermally stable co-reactant can be, e.g., a bismaleimides, a benzoxazine, a cyanate ester, an allyl resin, a vinyl ether resin, a phenolic resin or a combination thereof.

The compositions include coatings, films and other form. In some aspects, the compositions are adhesive, such as adhesive films.

The invention includes compositions that are uncured as well as compositions that are cured.

The thermo-oxidation-resistant compositions are the product of a condensation of at least one diamine with at least one dianhydride.

The at least one diamine can be 2,2-Bis[4-(4-aminophenoxy)phenyl] hexafluoropropane; 4,4-bis(4-amino-2-trifluoromethylphenoxy) biphenyl; 4,4′(Hexafluoroisopropylidene)bis[(4-aminophenoxy)benzene]; 4,4′-(Hexafluoroisopropylidene) dianiline; 3,3′-(Hexafluoroisopropylidene)dianiline; 4,4′-Diamino-2,2′-bis(trifluoromethyl)biphenyl; 1,4-Bis(4-amino-2-trifluoromethylphenoxy)benzene; 4,4′-Diaminooctafluorobiphenyl; 2,3,5,6-Tetrafluoro-1,4-phenylenediamine; 2,4,5,6-Tetrafluoro-1,3-phenylenediamine, bis(3-aminophenyl)sulfone; 1,4-bis(4-aminophenoxy)benzene; 4,4′-bis(4-aminophenoxy)biphenyl; bis[4-(4-aminophenoxy)phenyl]sulphone; 4,4′-diaminodiphenyl ether, and combinations thereof. The diamine can have a structure selected from:

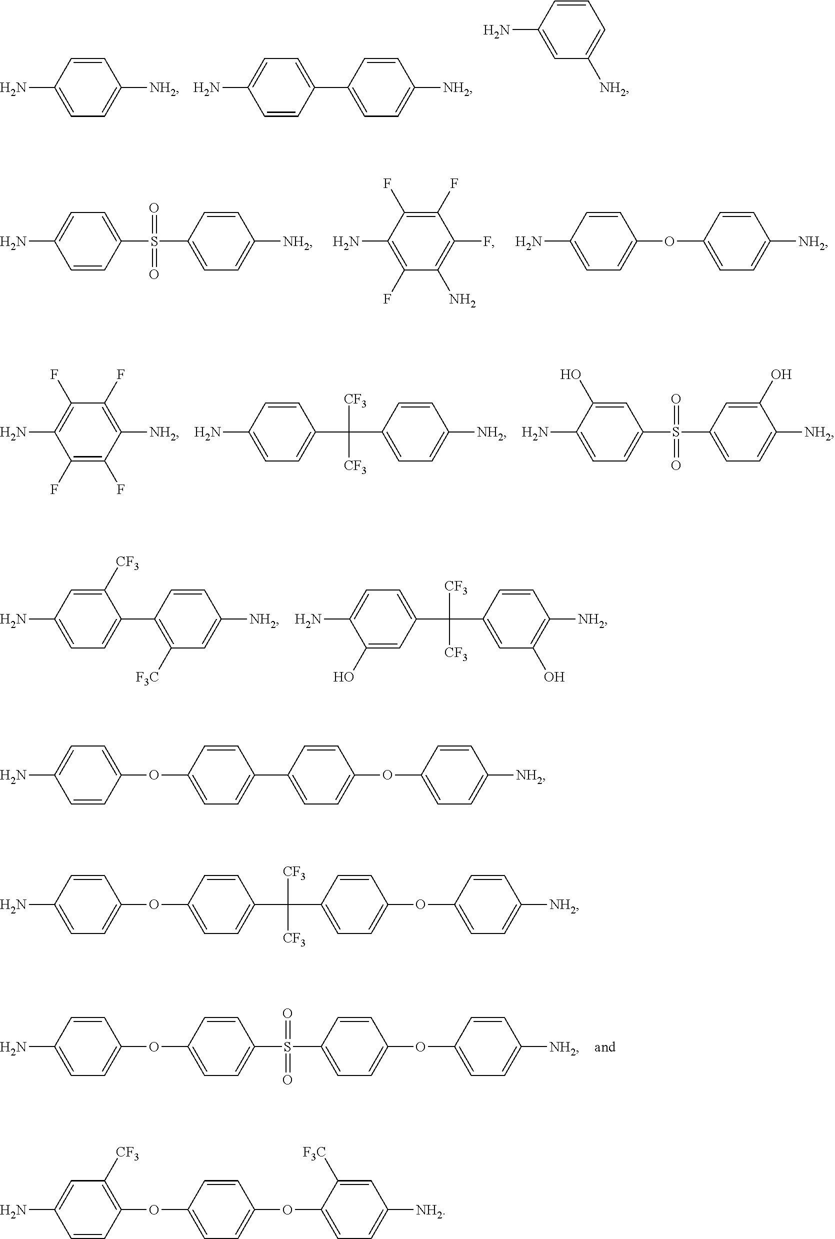

The at least one dianhydride is selected from the group consisting of 4,4′-(hexafluoroisopropylidene)diphthalic anhydride; pyromellitic dianhydride; diphenyl-3,3′,4,4′-tetracarboxylic dianhydride; 2,3,6,7-naphthalenetetracarboxylic 2,3,6,7-dianhydride; diphenyl-2,3,3′, 4′-tetracarboxylic dianhydride, and combinations thereof. The dianhydride can, for example, have a structure selected from:

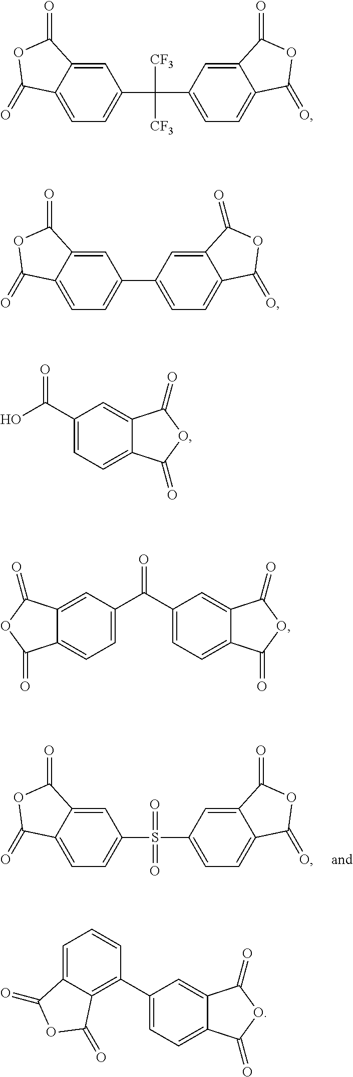 [SMILES: O=C1OC(=O)c2cc(C(c3ccc4c(c3)C(=O)OC4=O)(C(F)(F)F)C(F)(F)F)ccc21 ; O=C1OC(=O)c2cc(-c3ccc4c(c3)C(=O)OC4=O)ccc21 ; O=C(O)c1ccc2c(c1)C(=O)OC2=O ; O=C(c1ccc2c(c1)C(=O)OC2=O)c1ccc2c(c1)C(=O)OC2=O ; O=C1OC(=O)c2cc(S(=O)(=O)c3ccc4c(c3)C(=O)OC4=O)ccc21 ; O=C1OC(=O)c2cc(-c3cccc4c3C(=O)OC4=O)ccc21]

In one embodiment, the compound is the condensation product of 2,2-Bis[4-(4-aminophenoxy)phenyl] hexafluoropropane and 4,4′-(hexafluoroisopropylidene)diphthalic anhydride.

In certain embodiments, the compounds include one or more functionalization, such as a terminal functionalization. The functionalization (i.e., functional group) can be selected from benzoxazines, maleimides, citraconimides, itaconimide, and combinations thereof.

The invention also provides assemblies of one or more light emitting diodes (LED) coated on at least one surface with a cured layer (e.g., a coating or film) of the thermo-oxidation-resistant composition of the invention. For example, the LED can be encapsulated in the cured layer of the thermo-oxidation-resistant composition. The assembly can be, for example, a light bulb, such as a consumer light bulb or an aerospace light bulb.

Also provided are assemblies of a housing having at one or more light emitting diode (LED) disposed thereon, where the LED is capable of electrical communication with a power supply; and a lens manufactured from a cured, thermo-oxidation-resistant optical resin comprising that includes at least one compound of the invention, such as a compound of Formula I as described herein.

Typically, the lens transmits substantially all visible light passing through it, such as at least about 90%, at about least 95%, at least about 98%, or at least about 99% of the visible light passing through it. In certain aspects of the invention, the lens blocks substantially all UV light passing through it. Typically, the lens continues to transmit substantially all visible light passing through it after exposure to an air or oxygen environment at temperatures above 250° C., while continuing to block UV light passing through it after exposure to an air or oxygen environment at temperatures above 250° C.

In certain embodiments, the lens is lens is substantially colorless and can remain substantially colorless after exposure to an air or oxygen environment at temperatures above 250° C.

The invention also provides systems for providing light, comprising the assembly described above, and a power supply in electrical communication with the LED. The power supply can be, for example a battery, 110 V household current, 220 V household or industrial current, a computer, a terrestrial solar photovoltaic power source and an aerospace solar photovoltaic power source.

The thermo-oxidation-resistant compositions and coatings can include at least one thermally-stable (e.g., to at least about 250° C. or at least about 400° C.) or coupling agent (e.g., silane coupling agents, titanium coupling agents, zirconium coupling agents and combinations thereof), filler (e.g. silica, perfluorinated hydrocarbons, graphite, carbon black, carbon nanotubes, POSS, boron nitride, silver, and copper alloys and combinations thereof), co-reactant (e.g., bismaleimides, cyanate esters, benzoxazines, allyl resins, vinyl ether resins, phenolic resins and combinations thereof) or a combination of any coupling agents, fillers and co-reactants.

In certain aspects of the invention, the thermo-oxidation-resistant compounds, compositions and coatings are cured by any method known in the art, including heat-curing.

Also provided are assemblies that include at least one light emitting diode (LED) coated on at least one surface with a cured layer of the thermo-oxidation-resistant coating described herein. In some embodiments, the LED is encapsulated in a cured layer of thermo-oxidation-resistant coating, such as a film. In certain aspects, the assembly is a consumer light bulb or an aerospace light bulb.

The present invention also provides assemblies that include: a housing; at least one light emitting diode (LED) disposed on the housing, where the LED is capable of electrical communication with a power supply; and a lens manufactured from a cured, thermo-oxidation-resistant optical resin comprising at least one compound described herein. In certain embodiments of the invention, the lens transmits substantially all visible light passing through it, such as at least about 90%, at about least 95% or at least about 99% of the visible light passing through it. In particular aspects, the lens transmits substantially all visible light passing through it after exposure to high temperature (>250°) and/or oxidizing conditions (air or oxygen environment).

In certain embodiments, the lens is colorless or substantially colorless, and in certain aspects of this embodiment, remains colorless or substantially colorless after exposure to high temperature (>250°) and/or oxidizing conditions (air or oxygen environment)

Also provided by the invention are systems that include an LED-containing assembly described herein, and a power supply in electrical communication with the LED. The power supply can be, for example, a battery, 110 V household current, 220 V household or industrial current, a computer, a terrestrial solar photovoltaic power source and an aerospace solar photovoltaic power source.

Also provided are methods for protecting an object from at least one environmental condition coating the object on at least one surface or on all surfaces or sides, with the thermo-oxidation-resistant coating described herein, followed by curing the coating. The environmental condition(s) that the methods of the invention protect against include an air, oxygen or oxidizing environment at a temperature above 250° C., and further include protection from dust, moisture, and UV light and the like.

The object protected can be an electronics element, such as microelectronics element, which can be a chip, a diode (e.g. light emitting diode (LED)), or a package. In certain aspect, the object is under the hood or near the engine of a vehicle selected from the group consisting of: an automobile, a truck, a ship, a military vehicle, an airplane, and a spaces vehicle or any feature thereof.

The invention also provides methods for preparing a prepreg by immersing a reinforcing fiber (which can be a woven or unwoven fabric), in a liquid formulation of an uncured composition described herein. Thereafter, the prepreg can be drained to remove excess liquid formulation and dried for storage. The invention thus also includes prepregs comprising cured and uncured thermo-oxidation-resistant compositions described, which may be prepared as described herein.

The invention also provides method for preparing copper-clad laminates (CCL) by disposing copper on one (single-sided CCL) or both sides (double-sided CCL) of a prepreg of the invention. The copper can be disposed by electroplating or by laminating copper foil to the one or the both sides of the prepreg. The invention thus also includes single- and double-sided CCLs comprising prepregs comprising a reinforcing fiber impregnated with a thermo-oxidation-resistant composition of the invention having copper disposed on one or both sides, which may be prepared as described above, or by any other method known in the art.

The invention also provides methods for preparing printed circuit boards (PCBs) form the providing the CCLs of the invention, by etching circuit traces in the copper disposed on the one or the both sides of the CCL.

The invention also provides method for preparing flexible copper clad laminates (FCCLs) by applying an adhesive to one of both sides of a film form of a cured or uncured composition described herein, followed by laminating copper foil to the adhesive on the one or the both sides of the film. In certain embodiments, the film is an adhesive film and the copper foil can be laminated to the film without an additional adhesive. The invention thus includes single- and double-sided FCCLs comprising a film form (which can be an adhesive or non-adhesive film) of a composition described herein, having copper foil laminated to one or both sides of the film, with or without an additional adhesive layer between each copper foil and the film.

The invention also provides thin, flexible electronic circuits, that include a layer of adhesive film of a cured composition described herein, with copper circuit traces on one or both sides of the adhesive film. The thin, flexible electronic circuits can be prepared by etching circuit traces in the copper foil on one or both sides of an FCCL described herein.

### BRIEF DESCRIPTION OF THE DRAWINGS

FIG. 1A is a diagram illustrating a light emitting diode (LED) 1.

FIG. 1B is a diagram illustrating an LED assembly (LED lightbulb) 10 including an LED 1, housing 13, and a lens 14.

FIG. 1C is a schematic diagram illustrating an LED system 100a including an LED assembly 10, and a battery power supply 25.

FIG. 1D is a schematic diagram illustrating an LED system 100b including an LED assembly 10, and a solar photovoltaic power supply 30.

FIG. 2 is a graph showing weight loss during thermal aging of Compound 1 at 400° C. over time.

FIG. 3 is a graph showing transmittance of light through a film sample of Compound 1.

FIG. 4 is a graph showing weight loss during thermal aging of Compound 6 at 400° C. over time.

FIG. 5 is a graph showing weight loss during thermal aging of Compound 7 at 400° C. over time.

FIG. 6A-6C are photographs of thin films (25 μm) of polyimide Compound 1 (EXAMPLE 1) post-cure (FIG. 6A); after 24 hours thermal aging at 250° C. (FIG. 6B); and after 3,000 hours at 250° C. (FIG. 6C).

FIGS. 7A and 7B are photographs of thin films (25 μm) of polyimide Compound 6 (EXAMPLE 7) post-cure (FIG. 7A); and after 24 hours thermal aging at 250° C. (FIG. 7B).

FIGS. 8A and 8B are photographs of thin films (25 μm) of polyimide Compound 5 (EXAMPLE 6) post-cure (FIG. 8A); and after 24 hours thermal aging at 250° C. (FIG. 8B).

FIG. 9 is a schematic flow diagram illustrating the process of making a printed circuit board including preparing a prepreg, laminating copper onto the prepreg, and etching a circuit pattern on the copper-cladding. Arrows A-E indicate steps in the process.

FIG. 10 is a cross-sectional view through the structures at plane XVII of FIG. 9.

FIG. 11A is a schematic flow diagram illustrating the process of producing a one-sided flexible copper-clad laminate (FCCL) according to one embodiment of the invention that includes an adhesive layer. Arrows A and B indicate steps in the process.

FIG. 11B is a schematic flow diagram illustrating the process of producing a one-sided flexible copper-clad laminate (FCCL) according an embodiment of the invention that includes layers of adhesive. Arrows A and B indicate steps in the process.

FIG. 12A is a schematic flow diagram illustrating the process of producing a one-sided flexible copper-clad laminate (FCCL) according to one embodiment of the invention that omits an adhesive layer. Arrows A and B indicate steps in the process.

FIG. 12B is a schematic flow diagram illustrating the process of producing a one-sided flexible copper-clad laminate (FCCL) according an embodiment of the invention that excludes layers of adhesive. Arrows A and B indicate steps in the process.

### DETAILED DESCRIPTION

It is to be understood that both the foregoing general description and the following detailed description are exemplary and explanatory only and are not restrictive of the invention claimed. As used herein, the use of the singular includes the plural unless specifically stated otherwise. It is to be understood that as used in the specification and in the claims, “a” or “an” can mean one or more, depending upon the context in which it is used. Thus, reference to “a compound” can mean that at least one compound molecule is used, but typically refers to a plurality of compound molecules, which may be the same or different species. For example, “a compound having a structure according to the following Formula I” can refer to a single molecule or a plurality of molecules encompassed by the formula, as well all or a subset of the species the formula describes. As used herein, “or” means “and/or” unless stated otherwise. Furthermore, use of the term “including” as well as other forms, such as “includes,” and “included,” is not limiting.

The section headings used herein are for organizational purposes only and are not to be construed as limiting the subject matter described.

Unless specific definitions are provided, the nomenclatures utilized in connection with, and the laboratory procedures and techniques of analytical chemistry, synthetic organic and inorganic chemistry described herein are those known in the art, such as those set forth in “IUPAC Compendium of Chemical Terminology: IUPAC Recommendations (The Gold Book)” (McNaught ed.; International Union of Pure and Applied Chemistry, 2^{nd} Ed., 1997) and “Compendium of Polymer Terminology and Nomenclature: IUPAC Recommendations 2008” (Jones et al., eds; International Union of Pure and Applied Chemistry, 2009). Standard chemical symbols are used interchangeably with the full names represented by such symbols. Thus, for example, the terms “hydrogen” and “H” are understood to have identical meaning. Standard techniques may be used for chemical syntheses, chemical analyses, and formulation.

### Definitions

“About” as used herein, means that a number referred to as “about” comprises the recited number plus or minus 1-10% of that recited number. For example, “about” 100 degrees can mean 95-105 degrees or as few as 99-101 degrees, depending on the situation. Whenever it appears herein, a numerical range such as “1 to 20” refers to each integer in the given range; e.g., “1 to 20 carbon atoms” means that an alkyl group can contain only 1 carbon atom, 2 carbon atoms, 3 carbon atoms, etc., up to and including 20 carbon atoms (although the term “alkyl” also includes instances where no numerical range of carbon atoms is designated). Where “about” modifies a range expressed in non-integers, it means the recited number plus or minus 1-10% to the same degree of significant figures expressed. For example, about 1.50 to 2.50 mM can mean as little as 1.35 mM or as much as 2.75 mM or any amount in between in increments of 0.01. Where a range described herein includes decimal values, such as “1.2% to 10.5%”, the range refers to each decimal value of the smallest increment indicated in the given range; e.g. “1.2% to 10.5%” means that the percentage can be 1.2%, 1.3%, 1.4%, 1.5%, etc. up to and including 10.5%; while “1.20% to 10.50%” means that the percentage can be 1.20%, 1.21%, 1.22%, 1.23%, etc. up to and including 10.50%.

As used herein, the term “substantially” refers to a great extent or degree. More specifically, “substantially all” or equivalent expressions, typically refers to at least about 90%, frequently at least about 95%, often at least 99%, and more often at least about 99.9%. “Not substantially” refers to less than about 10%, frequently less than about 5%, and often less than about 1% such as less than 5%, less than 4%, less than 3%, less than 2%, or less than 1%. “Substantially free” or equivalent expressions, typically refers to less than about 10%, frequently less than about 5%, often less than about 1%, and in certain aspects less than about 0.1%.

“Adhesive” or “adhesive compound” as used herein, refers to any substance that can adhere or bond two items together. Implicit in the definition of an “adhesive composition” or “adhesive formulation” is the fact that the composition or formulation is a combination or mixture of more than one species, component or compound, which can include adhesive monomers, oligomers, and/or polymers along with other materials, whereas an “adhesive compound” refers to a single species, such as an adhesive polymer or oligomer.

More specifically, “adhesive composition” refers to un-cured mixtures in which the individual components in the mixture retain the chemical and physical characteristics of the original individual components of which the mixture is made. Adhesive compositions are typically malleable and may be liquids, pastes, gels, films or another form that can be applied to an item so that it can be bonded to another item.

“Cured adhesive,” “cured adhesive composition” or “cured adhesive compound” refers to adhesive components and mixtures obtained from reactive curable original compounds or mixtures thereof which have undergone a chemical and/or physical changes such that the original compounds or mixtures are transformed into a solid, substantially non-flowing material. A typical curing process may involve crosslinking.

“Curable” means that an original compound or composition can be transformed into a solid, substantially non-flowing material by means of chemical reaction, crosslinking, radiation crosslinking, or a similar process. Thus, adhesive compounds and compositions of the invention are curable, but unless otherwise specified, the original compounds and compositions are not cured.

“Conformal coatings” as used herein, refers to a material applied to electronic circuitry to act as protection against moisture, dust, chemicals, and temperature extremes that, if uncoated, could result in damage or failure of the electronics to function properly. Typically, the electronic circuitry or assemblies thereof is coated with a layer of transparent conformal coating to protect the electronics from harsh environment. In some instances, the conformal coating is transparent such that the circuitry can be visually inspected. Suitably chosen conformal coatings can also reduce the effects of mechanical stress, vibration and extreme temperatures. For example, in a chip-on-board packaging process, a silicon die is mounted on the board with adhesive or a soldering, and then electrically connected by wire bonding. To protect the very delicate package, the whole chip-on-board is encapsulated in a conformal coating, commonly referred to as a “glob top”.

“Interlayer Dielectric Layer” or “ILD” refer to a layer of dielectric material disposed over a first pattern of conductive traces, separating it from a second pattern of conductive traces, which can be stacked on top of the first. Often, ILD layers are patterned or drilled to provide openings (referred to as “vias”, short for “vertical interconnect access” channels) allowing electrical contact between the first and second patterns of conductive traces in specific regions or in layers of a multilayer printed circuit board. Other regions of such ILD layers are devoid of vias to strategically prevent electrical contact between the conductive traces of first and second patterns or layers.

“Thermoplastic”, as used herein, refers to the ability of a compound, composition or other material (e.g. a plastic) to dissolve in a suitable solvent or to melt to a liquid when heated, and to freeze to a solid, often brittle and glassy, state when cooled sufficiently.

“Thermoset”, as used herein, refers to the ability of a compound, composition or other material, to irreversibly “cure”, resulting in a single three-dimensional network that has greater strength and less solubility compared to the un-cured material. Thermoset materials are typically polymers that may be cured, for example, through heat (e.g. above 200° C.), via a chemical reaction (e.g. epoxy ring-opening or free-radical polymerization) or through irradiation (with e.g., visible light, UV light, electron beam radiation, ion-beam radiation, or X-ray irradiation).

Thermoset materials, such as thermoset polymers and resins, are typically liquid or malleable forms prior to curing, and therefore may be molded or shaped into their final form, and/or used as adhesives. Curing transforms the thermoset material into a rigid, infusible and insoluble solid or rubber by a cross-linking process. Energy and/or catalysts are typically added to the uncured thermoset that causes thermoset molecules to react at chemically active sites (e.g., unsaturated or epoxy sites), thereby linking the thermoset molecules into a rigid, 3-dimensional structure. The cross-linking process forms molecules with higher molecular weight and resulting higher melting point. During the reaction, when the molecular weight of the polymer has increased to a point that the melting point is higher than the surrounding ambient temperature, the polymer becomes a solid material.

“Cross-linking,” as used herein, refers to the attachment of two or more oligomer or longer polymer chains by bridges of an element, a molecular group, a compound, or another oligomer or polymer. Crosslinking may take place upon heating or exposure to light; some crosslinking processes may occur at room temperature or a lower temperature. As cross-linking density is increased, the properties of a material can be changed from thermoplastic to thermosetting.

“Underfill,” “underfill composition” and “underfill material” are used interchangeably to refer to material, typically polymeric compositions, used to fill gaps between a semiconductor component, such as a semiconductor die, and a substrate. “Underfilling” refers to the process of applying an underfill composition to a semiconductor component-substrate interface, thereby filling the gaps between the component and the substrate.

The term “photoimageable”, as used herein, refers to the ability of a compound or composition to be selectively cured only in areas exposed to light. The exposed areas of the compound are thereby rendered cured and insoluble, while the unexposed area of the compound or composition remains un-cured and therefore soluble in a developer solvent. Typically, this operation is conducted using ultraviolet light as the light source and a photomask as the means to define where the exposure occurs. The selective patterning of dielectric layers on a silicon wafer can be carried out in accordance with various photolithographic techniques known in the art. In one method, a photosensitive polymer film is applied over the desired substrate surface and dried. A photomask containing the desired patterning information is then placed in close proximity to the photoresist film. The photoresist is irradiated through the overlying photomask by one of several types of imaging radiation including UV light, e-beam electrons, x-rays, or ion beam. Upon exposure to the radiation, the polymer film undergoes a chemical change (cross-links) with concomitant changes in solubility. After irradiation, the substrate is soaked in a developer solution that selectively removes the non-cross-linked or unexposed areas of the film.

The term “passivation” as used herein, refers to the process of making a material “passive” in relation to another material or condition. The term “passivation layers” (PLs) refers to layers that are commonly used to encapsulate semiconductor devices, such as semiconductor wafers, to isolate the device from its immediate environment and, thereby, to protect the device from oxygen, water, as well airborne or space-borne contaminants, dust, particulates, humidity and the like. Passivation layers are typically formed from inert materials that are used to coat the device. This encapsulation process also passivates semiconductor devices by terminating dangling bonds created during manufacturing processes and by adjusting the surface potential to either reduce or increase the surface leakage current associated with these devices. In certain embodiments of the invention, passivation layers contain dielectric material that is disposed over a microelectronic device. Such PLs are typically patterned to form openings therein (e.g. vias) that provide for making electrical contact to the microelectronic device. Often a passivation layer is the last dielectric material disposed over a device and serves as a protective layer.

“Passivation” as used herein, refers to the process of making a material “passive” in relation to another material or condition. The term “passivation layers” (PLs) refers to layers that are commonly used to encapsulate semiconductor devices, such as semiconductor wafers, to isolate the device from its immediate environment and, thereby, to protect the device from oxygen, water, as well airborne or space-borne contaminants, dust, particulates, humidity and the like. Passivation layers are typically formed from inert materials that are used to coat the device. This encapsulation process also passivates semiconductor devices by terminating dangling bonds created during manufacturing processes and by adjusting the surface potential to either reduce or increase the surface leakage current associated with these devices.

As used herein, “B-stageable” refers to the properties of an adhesive having a first solid phase followed by a tacky rubbery stage at elevated temperature, followed by yet another solid phase at an even higher temperature. The transition similarly to a thermoplastic material. Thus, such adhesives allow for low lamination temperatures from the tacky rubbery stage to the second solid phase is thermosetting. However, prior to thermosetting, the material behaves while providing high thermal stability.

A “die” or “semiconductor die” as used herein, refers to a small block of semiconducting material, on which a functional circuit is fabricated.

“Chip” as used herein, refers to die fabricated with a functional circuit, (e.g., a set of electronic circuits or an integrated circuit).

A “semiconductor package” or “package” is a metal, plastic, glass, or ceramic casing containing one or more discrete semiconductor devices or integrated circuits. Individual components are fabricated on semiconductor wafers (commonly silicon) before being diced into die, tested, and packaged. The package provides a means for connecting to the external environment, such as printed circuit board, via leads such as lands, balls, or pins; and protection against threats such as mechanical impact, chemical contamination, and light exposure. Electronic devices are often packaged as discrete, functional units or “components”. Exemplary devices and components include: transistors, thyristors, diodes, Integrated circuits, rectifiers, resistors, power sources, capacitors, inductors, transformers, amplifiers, transducers, sensors, switches and the like. The term “monomer” refers to a molecule that can undergo polymerization or copolymerization thereby contributing constitutional units to the essential structure of a macromolecule (i.e., a polymer).

“Polymer” and “polymer compound” are used interchangeably herein, to refer generally to the combined the products of a single chemical polymerization reaction. Polymers are produced by combining monomer subunits into a covalently bonded chain. Polymers that contain only a single type of monomer are known as “homopolymers,” while polymers containing a mixture of two or more different monomers are known as “copolymers”.

The term “copolymers” includes products that are obtained by copolymerization of two monomer species, those obtained from three monomers species (terpolymers), those obtained from four monomers species (quaterpolymers), and those obtained from five or more monomer species. It is well known in the art that copolymers synthesized by chemical methods include, but are not limited to, molecules with the following types of monomer arrangements:
alternating copolymers, which contain regularly alternating monomer residues;
periodic copolymers, which have monomer residue types arranged in a repeating sequence;
random copolymers, which have a random sequence of monomer residue types; statistical copolymers, which have monomer residues arranged according to a known statistical rule;
block copolymers, which have two or more homopolymer subunits linked by covalent bonds. The blocks of homopolymer within block copolymers, for example, can be of any length and can be blocks of uniform or variable length. Block copolymers with two or three distinct blocks are called diblock copolymers and triblock copolymers, respectively; and
star copolymers, which have chains of monomer residues having different constitutional or configurational features that are linked through a central moiety.

The skilled artisan will appreciate that a single copolymer molecule may have different regions along its length that can be characterized as an alternating, periodic, random, etc. A copolymer product of a chemical polymerization reaction may contain individual polymeric molecules and fragments that each differ in the arrangement of monomer units. The skilled artisan will further be knowledgeable in methods for synthesizing each of these types of copolymers, and for varying reaction conditions to favor one type over another.

Furthermore, the length of a polymer chain according to the present invention will typically vary over a range or average size produced by a reaction. The skilled artisan will be aware, for example, of methods for controlling the average length of a polymer chain produced in a given reaction and of methods for size-selecting polymers after they have been synthesized.

Unless a more restrictive term is used, “polymer” is intended to encompass homopolymers, and copolymers having any arrangement of monomer subunits as well as copolymers containing individual molecules having more than one arrangement. With respect to length, unless otherwise indicated, any length limitations recited for the polymers described herein are to be considered averages of the lengths of the individual molecules in polymer.

“Thermoplastic elastomer” or “TPE”, as used herein refers to a class of copolymers that consist of materials with both thermoplastic and elastomeric properties.

“Hard blocks” or “hard segments” as used herein refer to a block of a copolymer (typically a thermoplastic elastomer) that is hard at room temperature by virtue of a high melting point (Tm) or T_{g}. By contrast, “soft blocks” or “soft segments” have a T_{g} below room temperature.

As used herein, “oligomer” or “oligomeric” refers to a polymer having a finite and moderate number of repeating monomer structural units. Oligomers of the invention typically have 2 to about 100 repeating monomer units; frequently 2 to about 30 repeating monomer units; and often 2 to about 10 repeating monomer units; and usually have a molecular weight up to about 3,000.

“Polydispersity index” (PDI) or “heterogeneity index”, is a measure of the distribution of molecular mass in a given polymer sample. PDI is calculated by the following formula:

PDI=M_{w}/Mₙ

where M_{w} is the weight average molecular weight and Mₙ is the number average molecular weight.

As used herein, “aliphatic” refers to any alkyl, alkenyl, cycloalkyl, or cycloalkenyl moiety.

“Aromatic hydrocarbon” or “aromatic” as used herein, refers to compounds having one or more benzene rings.

“Alkane,” as used herein, refers to saturated straight-chain, branched or cyclic hydrocarbons having only single bonds. Alkanes have general formula CₙH₂ₙ₊₂.

“Cycloalkane,” refers to an alkane having one or more rings in its structure.

As used herein, “alkyl” refers to straight or branched chain hydrocarbyl groups having from 1 to about 500 carbon atoms. “Lower alkyl” refers generally to alkyl groups having 1 to 6 carbon atoms. The terms “alkyl” and “substituted alkyl” include, respectively, substituted and unsubstituted C₁-C₅₀₀ straight chain saturated aliphatic hydrocarbon groups, substituted and unsubstituted C₂-C₂₀₀ straight chain unsaturated aliphatic hydrocarbon groups, substituted and unsubstituted C₄-C₁₀₀ branched saturated aliphatic hydrocarbon groups, substituted and unsubstituted C₁-C₅₀₀ branched unsaturated aliphatic hydrocarbon groups.

For example, the definition of “alkyl” includes but is not limited to: methyl (Me), ethyl (Et), propyl (Pr), butyl (Bu), pentyl, hexyl, heptyl, octyl, nonyl, decyl, undecyl, ethenyl, propenyl, butenyl, penentyl, hexenyl, heptenyl, octenyl, nonenyl, decenyl, undecenyl, isopropyl (i-Pr), isobutyl (i-Bu), tert-butyl (t-Bu), sec-butyl (s-Bu), isopentyl, neopentyl, cyclopropyl, cyclobutyl, cyclopentyl, cyclohexyl, cycloheptyl, cyclooctyl, cyclopentenyl, cyclohexenyl, cycloheptenyl, cyclooctenyl, methylcyclopropyl, ethylcyclohexenyl, butenylcyclopentyl, tricyclodecyl, adamantyl, and norbornyl.

“Substituted” refers to compounds and moieties bearing substituents that include but are not limited to alkyl (e.g. C₁₋₁₀ alkyl), alkenyl, alkynyl, hydroxy, oxo, alkoxy, mercapto, cycloalkyl, substituted cycloalkyl, heterocyclic, substituted heterocyclic, aryl, substituted aryl (e.g., aryl C₁₋₁₀ alkyl or aryl C₁₋₁₀ alkyloxy), heteroaryl, substituted heteroaryl (e.g., heteroarylC₁₋₁₀alkyl), aryloxy, C₁₋₁₀ alkyloxy C₁₋₁₀ alkyl, aryl C₁₋₁₀ alkyloxyC₁₋₁₀ alkyl, C₁₋₁₀ alkylthioC₁₋₁₀ alkyl, aryl C₁₋₁₀ alkylthio C₁₋₁₀ alkyl, C₁₋₁₀ alkylamino C₁₋₁₀ alkyl, aryl C₁₋₁₀alkylamino C₁₋₁₀ alkyl, N-aryl-N—C₁₋₁₀ alkylamino C₁₋₁₀ alkyl, C₁₋₁₀ alkylcarbonyl C₁₋₁₀ alkyl, aryl C₁₋₁₀ alkylcarbonyl C₁₋₁₀ alkyl, C₁₋₁₀ alkylcarboxy C₁₋₁₀ alkyl, aryl C₁₋₁₀ alkylcarboxy C₁₋₁₀ alkyl, C₁₋₁₀ alkylcarbonylamino C₁₋₁₀ alkyl, and aryl C₁₋₁₀ alkylcarbonylamino C₁₋₁₀ alkyl, substituted aryloxy, halo, haloalkyl (e.g., trihalomethyl), cyano, nitro, nitrone, amino, amido, carbamoyl, ═O, ═CH—, —C(O)H, —C(O)O—, —C(O)—, —S—, —S(O)₂, —OC(O)—O—, —NR—C(O), —NR—C(O)—NR, —OC(O)—NR, where R is H or lower alkyl, acyl, oxyacyl, carboxyl, carbamate, sulfonyl, sulfonamide, sulfuryl, C₁₋₁₀ alkylthio, aryl C₁₋₁₀ alkylthio, C₁₋₁₀ alkylamino, aryl C₁₋₁₀ alkylamino, N-aryl-N—C₁₋₁₀ alkylamino, C₁₋₁₀ alkyl carbonyl, aryl C₁₋₁₀ alkylcarbonyl, C₁₋₁₀ alkylcarboxy, aryl C₁₋₁₀ oalkylcarboxy, C₁₋₁₀ alkyl carbonylamino, arylC₁₋₁₀ alkylcarbonylamino, tetrahydrofuryl, morpholinyl, piperazinyl, and hydroxypyronyl.

In addition, as used herein “C₃₆” refers to all possible structural isomers of a 36-carbon aliphatic moiety, including branched isomers and cyclic isomers with up to three carbon-carbon double bonds in the backbone. A non-limiting example of a moiety that “C₃₆” refers to is the moiety comprising a cyclohexane core and four long “arms” attached to the core, as illustrated below:

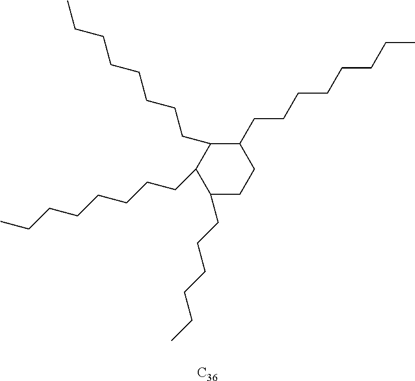 [SMILES: CCCCCCCCC1CCC(CCCCCC)C(CCCCCCCC)C1CCCCCCCC ; "C36"]

As used herein, “cycloalkyl” refers to cyclic ring-containing groups containing about 3 to about 20 carbon atoms, typically about 3 to about 15 carbon atoms. In certain embodiments, cycloalkyl groups have about 4 to about 12 carbon atoms, and in yet further embodiments, cycloalkyl groups have about 5 to about 8 carbon atoms. “Substituted cycloalkyl” refers to cycloalkyl groups further bearing one or more substituents” as set forth above.

As used herein, the term “aryl” refers to an unsubstituted, mono-, di- or trisubstituted monocyclic, polycyclic, biaryl aromatic groups covalently attached at any ring position capable of forming a stable covalent bond, certain preferred points of attachment being apparent to those skilled in the art (e.g., 3-phenyl, 4-naphtyl). “Substituted aryl” refers to aryl groups further bearing one or more substituents as set forth above.

Specific examples of moieties encompassed by the definition of “aryl” include but are not limited to phenyl, biphenyl, naphthyl, dihydronaphthyl, tetrahydronaphthyl, indenyl, indanyl, azulenyl, anthryl, phenanthryl, fluorenyl, pyrenyl and the like.

As used herein, “hetero” refers to groups or moieties containing one or more heteroatoms such as N, O, Si and S. Thus, for example “heterocyclic” refers to cyclic (i.e., ring-containing) groups having e.g. N, O, Si or S as part of the ring structure, and having 3 to 14 carbon atoms. “Heteroaryl” and “heteroalkyl” moieties are aryl and alkyl groups, respectively, containing e.g. N, O, Si or S as part of their structure. The terms “heteroaryl”, “heterocycle” or “heterocyclic” refer to a monovalent unsaturated group having a single ring or multiple condensed rings, from 1 to 8 carbon atoms and from 1 to 4 hetero atoms selected from nitrogen, sulfur or oxygen within the ring.

The definition of heteroaryl includes but is not limited to thienyl, benzothienyl, isobenzothienyl, 2,3-dihydrobenzothienyl, furyl, pyranyl, benzofuranyl, isobenzofuranyl, 2,3-dihydrobenzofuranyl, pyrrolyl, pyrrolyl-2,5-dione, 3-pyrrolinyl, indolyl, isoindolyl, 3H-indolyl, indolinyl, indolizinyl, indazolyl, phthalimidyl (or isoindoly-1,3-dione), imidazolyl. 2H-imidazolinyl, benzimidazolyl, pyridyl, pyrazinyl, pyradazinyl, pyrimidinyl, triazinyl, quinolyl, isoquinolyl, 4H-quinolizinyl, cinnolinyl, phthalazinyl, quinazolinyl, quinoxalinyl, 1,8-naphthyridinyl, pteridinyl, carbazolyl, acridinyl, phenazinyl, phenothiazinyl, phenoxazinyl, chromanyl, benzodioxolyl, piperonyl, purinyl, pyrazolyl, triazolyl, tetrazolyl, thiazolyl, isothiazolyl, benzthiazolyl, oxazolyl, isoxazolyl, benzoxazolyl, oxadiazolyl, thiadiazolyl, pyrrolidinyl-2,5-dione, imidazolidinyl-2,4-dione, 2-thioxo-imidazolidinyl-4-one, imidazolidinyl-2,4-dithione, thiazolidinyl-2,4-dione, 4-thioxo-thiazolidinyl-2-one, piperazinyl-2,5-dione, tetrahydro-pyridazinyl-3,6-dione, 1,2-dihydro-[1,2,4,5]tetrazinyl-3,6-dione, [1,2,4,5]tetrazinanyl-3,6-dione, dihydro-pyrimidinyl-2,4-dione, pyrimidinyl-2,4,6-trione, 1H-pyrimidinyl-2,4-dione, 5-iodo-1H-pyrimidinyl-2,4-dione, 5-chloro-1H-pyrimidinyl-2,4-dione, 5-methyl-1H-pyrimidinyl-2,4-dione, 5-isopropyl-1H-pyrimidinyl-2,4-dione, 5-propynyl-1H-pyrimidinyl-2,4-dione, 5-trifluoromethyl-1H-pyrimidinyl-2,4-dione, 6-amino-9H-purinyl, 2-amino-9H-purinyl, 4-amino-1H-pyrimidinyl-2-one, 4-amino-5-fluoro-1H-pyrimidinyl-2-one, 4-amino-5-methyl-1H-pyrimidinyl-2-one, 2-amino-1,9-dihydro-purinyl-6-one, 1,9-dihydro-purinyl-6-one, 1H-[1,2,4]triazolyl-3-carboxylic acid amide, 2,6-diamino-N.sub.6-cyclopropyl-9H-purinyl, 2-amino-6-(4-methoxyphenylsulfanyl)-9H-purinyl, 5,6-dichloro-1H-benzoimidazolyl, 2-isopropylamino-5,6-dichloro-1H-benzoimidazolyl, and 2-bromo-5,6-dichloro-1H-benzoimidazolyl. Furthermore, the term “saturated heterocyclic” represents an unsubstituted, mono-, di- or trisubstituted monocyclic, polycyclic saturated heterocyclic group covalently attached at any ring position capable of forming a stable covalent bond, certain preferred points of attachment being apparent to those skilled in the art (e.g., 1-piperidinyl, 4-piperazinyl and the like).

Hetero-containing groups may also be substituted. For example, “substituted heterocyclic” refers to a ring-containing group having 3 to 14 carbon atoms that contains one or more heteroatoms and also bears one or more substituents set forth above.

As used herein, “alkylaryl” refers to alkyl-substituted aryl groups and “substituted alkylaryl” refers to alkylaryl groups further bearing one or more substituents as set forth below.

As used herein, “arylalkyl” refers to aryl-substituted alkyl groups and “substituted arylalkyl” refers to arylalkyl groups further bearing one or more substituents as set forth below. Examples of arylalkyl and substituted arylalkyl include but are not limited to (4-hydroxyphenyl)ethyl and or (2-aminonaphthyl) hexenyl, respectively.

As used herein, “arylalkenyl” refers to aryl-substituted alkenyl groups and “substituted arylalkenyl” refers to arylalkenyl groups further bearing one or more substituents as set forth above.

As used herein, “arylalkynyl” refers to aryl-substituted alkynyl groups and “substituted arylalkynyl” refers to arylalkynyl groups further bearing one or more substituents as set forth above.

As used herein, “aroyl” refers to aryl-carbonyl species such as benzoyl and “substituted aroyl” refers to aroyl groups further bearing one or more substituents as set forth above.

As used herein, the term “phenol” includes compounds having one or more phenolic functions per molecule, as illustrated below:

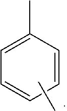

As used herein, “aroyl” refers to aryl-carbonyl species such as benzoyl and “substituted aroyl” refers to aroyl groups further bearing one or more substituents as set forth above.

The terms aliphatic, cycloaliphatic and aromatic, when used to describe phenols, refers to phenols to which aliphatic, cycloaliphatic and aromatic residues or combinations of these backbones are attached by direct bonding or ring fusion.

As used herein, “alkenyl,” “alkene” or “olefin” refers to straight or branched chain unsaturated hydrocarbyl groups having at least one carbon-carbon double bond and having about 2 to 500 carbon atoms. In certain embodiments, alkenyl groups have about 5 to about 250 carbon atoms, about 5 to about 100 carbon atoms, about 5 to about 50 carbon atoms or about 5 to about 25 carbon atoms. In other embodiments, alkenyl groups have about 6 to about 500 carbon atoms, about 8 to about 500 carbon atoms, about 10 to about 500 carbon atoms, about 20 to about 500 carbon atoms, about 50 to about 500 carbon atoms. In yet further embodiments, alkenyl groups have about 6 to about 100 carbon atoms, about 10 to about 100 carbon atoms, about 20 to about 100 carbon atoms, or about 50 to about 100 carbon atoms, while in other embodiments, alkenyl groups have about 6 to about 50 carbon atoms, about 6 to about 25 carbon atoms, about 10 to about 50 carbon atoms, or about 10 to about 25 carbon atoms. “Substituted alkenyl” refers to alkenyl groups further bearing one or more substituents as set forth above.

As used herein, “alkylene” refers to a divalent alkyl moiety, and “oxyalkylene” refers to an alkylene moiety containing at least one oxygen atom instead of a methylene (CH₂) unit. “Substituted alkylene” and “substituted oxyalkylene” refer to alkylene and oxyalkylene groups further bearing one or more substituents as set forth above.

As used herein, “alkynyl” refers to straight or branched chain hydrocarbyl groups having at least one carbon-carbon triple bond and having about 2 to about 100 carbon atoms, typically about 4 to about 50 carbon atoms, and frequently about 8 to about 25 carbon atoms. “Substituted alkynyl” refers to alkynyl groups further bearing one or more substituents as set forth above.

“Imide” as used herein, refers to a functional group having two carbonyl groups bound to a primary amine or ammonia. The general formula of an imide of the invention is:

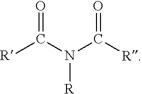

“Polyimides” are polymers of imide-containing monomers. Polyimides are typically linear or cyclic. Non-limiting examples of linear and cyclic (e.g. an aromatic heterocyclic polyimide) polyimides are shown below for illustrative purposes.

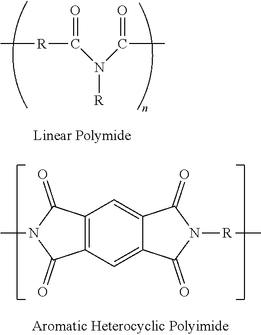

where R is an aromatic, heteroaromatic, aliphatic, or polymeric moiety.

“Maleimide,” as used herein, refers to an N-substituted maleimide having the formula as shown below:

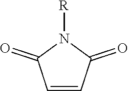

where R is an aromatic, heteroaromatic, aliphatic, or polymeric moiety.

“Bismaleimide” or “BMI”, as used herein, refers to compound in which two imide moieties are linked by a bridge, i.e. a compound a polyimide having the general structure shown below:

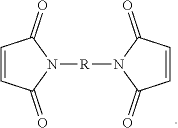

BMIs can cure through an addition rather than a condensation reaction, thus avoiding problems resulting from the formation of volatiles. BMIs can be cured by a vinyl-type polymerization of a pre-polymer terminated with two maleimide groups.

As used herein, the term “acrylate” refers to a compound bearing at least one moiety having the structure:

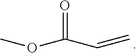

As used herein, the term “acrylamide” refers to a compound bearing at least one moiety having the structure:

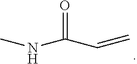

As used herein, the term “methacrylate” refers to a compound bearing at least one moiety having the structure:

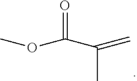

As used herein, the term “methacrylamide” refers to a compound bearing at least one moiety having the structure:

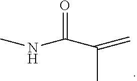

As used herein, “maleate” refers to a compound bearing at least one moiety having the structure:

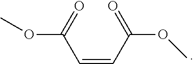

As used herein, the terms “citraconimide” and “citraconate” refer to a compound bearing at least one moiety having the structure:

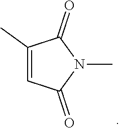

“Itaconimide” and “itaconate”, as used herein, refer to a compound bearing at least one moiety having the structure:

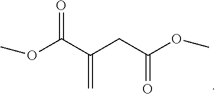

As used herein, “benzoxazine” refers to moieties including the following bicyclic structure:

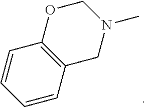

As used herein, the term “acyloxy benzoate” or “phenyl ester” refers to a compound bearing at least one moiety having the structure:

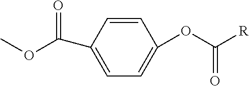

where R is H, lower alkyl, or aryl.

As used herein, “oxiranylene” or “epoxy” refers to divalent moieties having the structure:

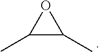

The term “epoxy” also refers to thermosetting epoxide polymers that cure by polymerization and crosslinking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and the like, and combinations thereof.

As used herein, “arylene” refers to a divalent aryl moiety. “Substituted arylene” refers to arylene moieties bearing one or more substituents as set forth above.

As used herein, “acyl” refers to alkyl-carbonyl species.

As used herein, the term “oxetane” refers to a compound bearing at least one moiety having the structure:

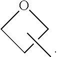

“Sulfonyl”, as used herein, refers to refers to a compound bearing at least one moiety having the structure:

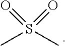

“Allyl” as used herein, refers to refers to a compound bearing at least one moiety having the structure:

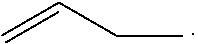

As used herein, the term “vinyl ether” refers to a compound bearing at least one moiety having the structure:

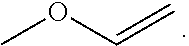

As used herein, the term “vinyl ester” refers to a compound bearing at least one moiety having the structure:

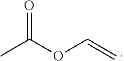

As used herein, “styrenic” refers to a compound bearing at least one moiety having the structure:

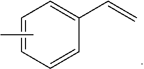

“Fumarate” as used herein, refers to a compound bearing at least one moiety having the structure:

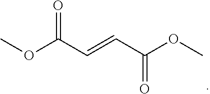

“Propargyl” as used herein, refers to a compound bearing at least one moiety having the structure:

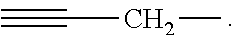

“Cyanate ester” as used herein, refers to a compound bearing at least one moiety having the structure:

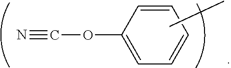

As used herein, “norbornyl” refers to a compound bearing at least one moiety having the structure:

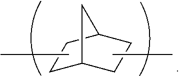

As used herein, the terms “halogen,” “halide,” or “halo” include fluorine, chlorine, bromine, and iodine.

As used herein “benzylic carbon” refers to a carbon atom (arrow) attached directly to a benzene ring, and “benzylic hydrogen” refers to hydrogen atoms (circled) attached directly to a benzylic carbon as shown below:

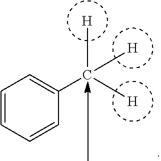

The terms “primary hydrogen”, “10 hydrogen”, “primary hydrogen atom”, and “10 hydrogen atom” are used interchangeably herein to refer to a hydrogen atom (circled) attached to a C that is bonded to one other C atom, as shown below:

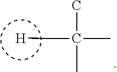

The terms “secondary hydrogen”, “2° hydrogen”, “secondary hydrogen atom”, and “20 hydrogen atom” are used interchangeably herein refer to a hydrogen atom (circled) attached to a C that is bonded to two other C atom, as shown below:

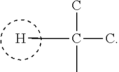

The terms “tertiary hydrogen”, “30 hydrogen”, “tertiary hydrogen atom”, and “30 hydrogen atom” are used interchangeably herein refer to a hydrogen atom (circled) attached to a C that is bonded to three other C atom, as shown below:

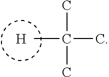

As used herein, the term “free radical initiator” refers to any chemical species which, upon exposure to enough energy (e.g., light, heat, or the like), decomposes into parts, which are uncharged, but every one of such part possesses at least one unpaired electron.

As used herein, the term “coupling agent” refers to chemical species that are capable of bonding to a mineral surface and which also contain polymerizably reactive functional group(s) to enable interaction with the adhesive composition. Coupling agents thus facilitate linkage of the die-attach paste to the substrate to which it is applied.

“Diamine”, as used herein, refers generally to a compound or mixture of compounds, where each species has 2 amine (—NH₂) groups.

“Anhydride” as used herein, refers to a compound bearing at least one moiety having the structure:

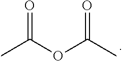

“Dianhydride,” as used herein, refers generally to a compound or mixture of compounds, where each species has 2 anhydride (—NH₂) groups.

The term “solvent,” as used herein, refers to a liquid that dissolves a solid, liquid, or gaseous solute, resulting in a solution. “Co-solvent” refers to a second, third, etc. solvent used with a primary solvent.

As used herein, “polar protic solvents” are ones that contain an O—H or N—H bond, while “polar aprotic solvents” do not contain an O—H or N—H bond.

As used herein the term “dielectric constant” and abbreviation “Dk” or “relative permittivity”, is the ratio of the permittivity (a measure of electrical resistance) of a substance to the permittivity of free space (which is given a value of 1). In simple terms, the lower the Dk of a material, the better it will act as an insulator. As used herein, “low dielectric constant” refers to materials with a Dk less than that of silicon dioxide, which has Dk of 3.9. Thus, “low dielectric constant refers” to a Dk of less than 3.9, typically, less than about 3.5, and most often less than about 3.0.

As used herein the term “dissipation dielectric factor”, “dissipation dielectric factor”, and abbreviation “Df” are used herein to refer to a measure of loss-rate of energy in a thermodynamically open, dissipative system. In simple terms, Df is a measure of how inefficient the insulating material of a capacitor is. It typically measures the heat that is lost when an insulator such as a dielectric is exposed to an alternating field of electricity. The lower the Df of a material, the better its efficiency. “Low dissipation dielectric factor” typically refers to a Df of less than about 0.01 at 1 GHz frequency, frequently less than about 0.005 at 1 GHz frequency, and most often 0.001 or lower at 1 GHz frequency.

“Glass transition temperature” or “T_{g}” is used herein to refer to the temperature at which an amorphous solid, such as a polymer, becomes brittle on cooling, or soft on heating. More specifically, it defines a pseudo second order phase transition in which a supercooled melt yields, on cooling, a glassy structure and properties like those of crystalline materials e.g. of an isotropic solid material.

“Modulus” or “Young's modulus” as used herein, is a measure of the stiffness of a material. Within the limits of elasticity, modulus is the ratio of the linear stress to the linear strain, which can be determined from the slope of a stress-strain curve created during tensile testing.

The “Coefficient of Thermal Expansion” or “CTE” is a term of art describing a thermodynamic property of a substance. The CTE relates a change in temperature to the change in a material's linear dimensions. As used herein “α₁ CTE” or “α₁” refers to the CTE before the T_{g}, while “α₂ CTE” refers to the CTE after the T_{g}.

“Thixotropy” as used herein, refers to the property of a material which enables it to stiffen or thicken in a relatively short time upon standing, but upon agitation or manipulation to change to low-viscosity fluid; the longer the fluid undergoes shear stress, the lower its viscosity. Thixotropic materials are therefore gel-like at rest but fluid when agitated and have high static shear strength and low dynamic shear strength, at the same time.

“Thermogravimetric analysis” or “TGA” refers to a method of testing and analyzing a material to determine changes in weight of a sample that is being heated in relation to change in temperature.

“Decomposition onset” refers to a temperature at which the loss of weight in response to the increase of the temperature indicates that the sample is beginning to degrade.

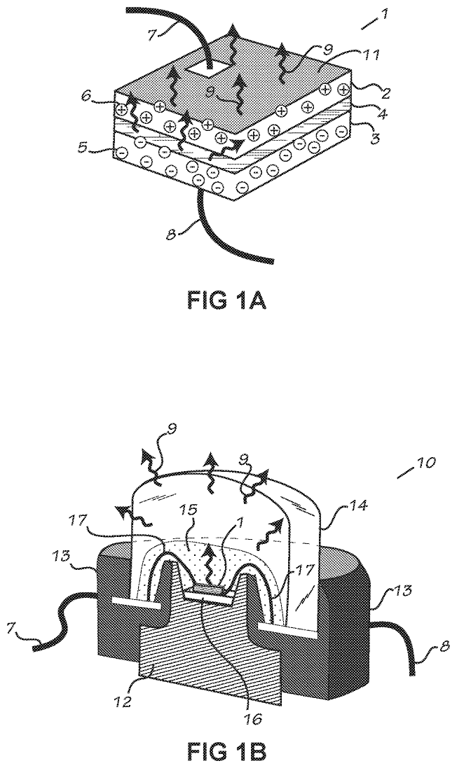

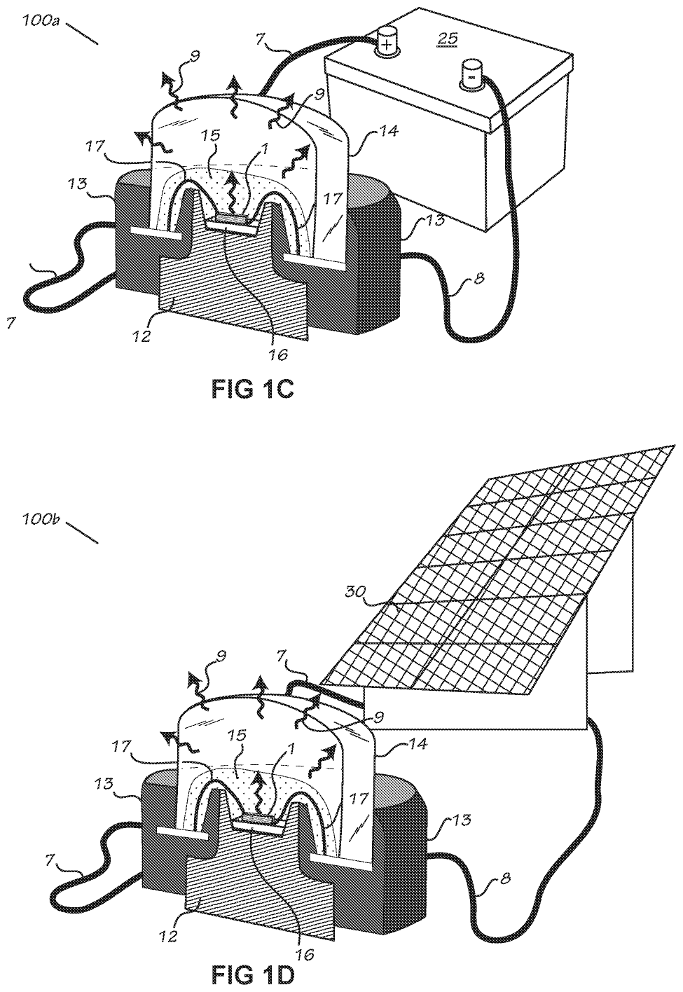

“LED” or “light emitting diode” as used herein, refers to a solid-state semiconductor device that converts electrical energy into light. An LED 1, which is illustrated in FIG. 1A, includes an active semiconductor material layer or region 3 (“active layer or “active region”; also known as the “depletion layer”) between a layer of P-type semiconductor 2 (“P-layer”) and a layer of N-type semiconductor 4 (“N-layer”). The P-layer 2 is doped with an electron acceptor, which forms “holes” 6 where electrons could be; while the N-layer 3 is doped with electron donor, which forms free electrons 5. The LED 1 is equipped with or connected to a cathode lead 8 and an anode lead 7 to supply electricity to the diode from a power source. Current applied across LED 1 causes the electrons 5 and holes 6 to move into the active layer and combine in a process that releases energy in the form of photons of light 9 and heat. Heat is typically dissipated through a heat sink 12 (see FIG. 1B). The light can be directed through a reflective coating or cap 11 on the LED as shown in FIG. 1A, or through reflectors (not shown) in an LED assembly 10 (such as an LED lightbulb) as shown in FIG. 1B.

An “LED assembly”, 10, such as an LED lightbulb, is illustrated in FIG. 1B. In this embodiment, the LED 1 is protected by an encapsulant 15 and mounted in a housing 13. The LED may further be protected from electrostatic discharge by mounting on a silicon sub-mount chip 16. Wires 17 connect the LED to an anode lead 7 and a cathode lead 8, which are in turn connected to the positive and negative and terminals, respectively, of a battery or power supply.

Many electronics, aerospace, and automotive applications require the use of polymers that are resistant to thermo-oxidative, and photochemical degradation. An example is LED and OLED applications in which polymers may be exposed to temperatures of 250° C. for several thousand hours.

The present invention is based on the discovery that fluorination of certain polyimides of the invention imparts increased resistance to thermo-oxidative and photochemical degradation.

Furthermore, excessive fluorination (>25% by weight) leads to a lowering of the surface energy and can lower Dk and Df, which are desirable properties in electronics manufacturing, e.g., for dielectric layers and in making copper clad laminates, and also provides anti-stiction that is needed in seals and gaskets.

The invention curable polyimides can be described according to the following general structure:

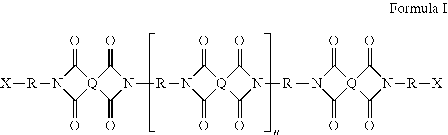

where each R is independently a substituted or unsubstituted aromatic, heteroaromatic, or fluorinated aromatic moiety, with the proviso that R contains no primary, secondary, tertiary or benzylic hydrogens; each Q is a substituted or unsubstituted aromatic, heteroaromatic, or fluorinated aromatic moiety, with the proviso that Q contains no primary, secondary, tertiary or benzylic hydrogens; X is a curable moiety; and n is 0 or an integer having the value from 1-100.

In certain aspects of the invention, n is about 20 to about 100. In other embodiments, n about 20 to about 90, about 30 to about 90, about 40 to about 100, or about 50 to about 90.

In certain embodiments, R is selected from the group consisting of:

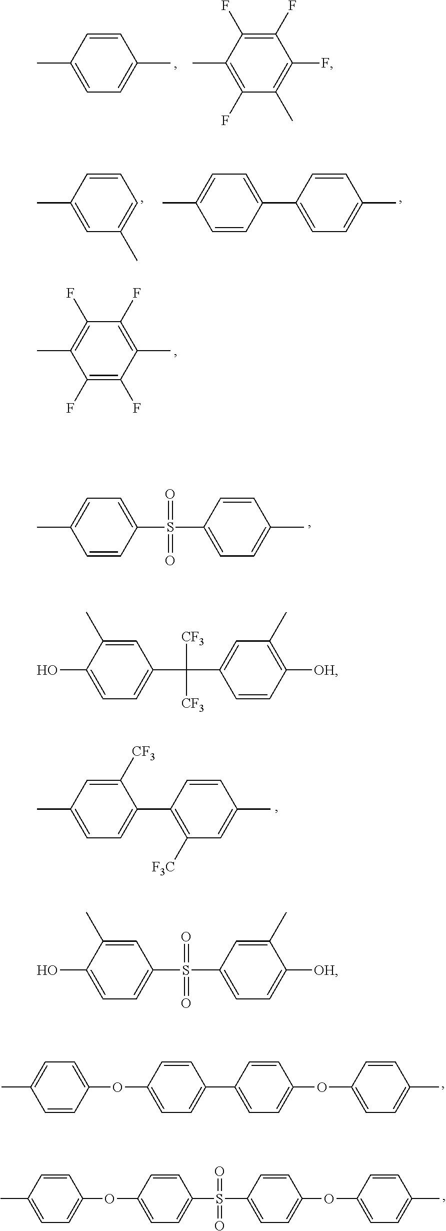

and mixtures thereof.

In certain aspects of the invention, each R has 0-12 fluorine atoms, typically at least 1 fluorine atom, often at least 2 fluorine atoms, more often at least 3 fluorine atoms, frequently at least 4 fluorine atoms, and most often at least 6 fluorine atoms. In other embodiments, R includes at least one sulfonyl group.

In certain aspects, at least 60%, at least 70%, at least 80%, at least 90% of all, at least 95% or at least 99% of all Qs are fluorinated. In other embodiments, Q includes at least one sulfonyl group.

In certain embodiments, Q is selected from the group consisting of:

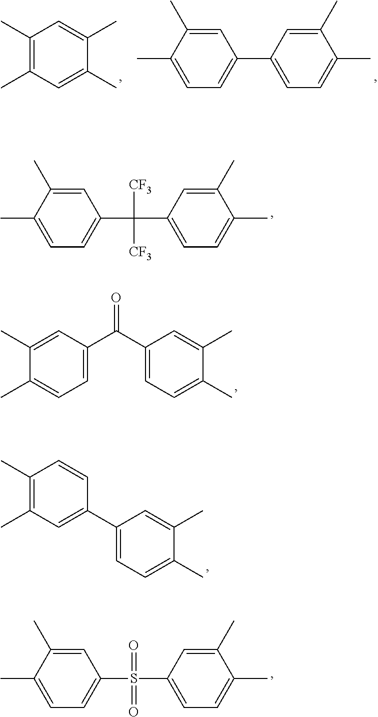

and mixtures thereof.

In certain embodiments, X is selected from the group consisting maleimides, citraconimides, itaconimides, and benzoxazines. In some aspects, X is fluorinated. When X is fluorinated, it typically has at least 1 fluorine atom, often at least 2 fluorine atoms, more often at least 3 fluorine atoms, frequently at least 4 fluorine atoms, more frequently at least 6 fluorine atoms, and in certain instances, up to 12 fluorine atoms.

Polyimides of the invention are synthesized by contacting at least one diamine with at least one dianhydride in a solvent, such as an aromatic solvent, which may anisole. Typically, the reaction solution does not discolor during the synthesis. In certain aspects, the solvent prevents or minimizes discoloration of the polyimide or reactants during the synthesis. The solution of at least one diamine and at least one dianhydride is then heated to reflux to produce a polyimide, with the azeotropic removal of the water.

The synthesis of polyamic acids, such as polyimides, is typically conducted in polar aprotic solvents such as N-methylpyrollidone (NMP), dimethylsulfoxide (DMSO), dimethylformamide (DMF), dimethylacetamide (DMAC), and the like. However, solutions of many polyamic acids described herein in polar aprotic solvents darken quickly when heated and eventually turn black in color. Therefore, synthesis in polar aprotic solvents gives polyimide solutions that are not suitable when colorless or low color products are required.

Surprisingly, anisole has been found to obviate the problem of darkening and synthesis in anisole provides polyimides that have very low color. The aromaticity of anisole as well as the ether linkage can facilitate dissolving many of the starting reagents, especially when heated to above 100° C. Water is evolved during the diamine-dianhydride condensation reaction materials become increasingly soluble and form a homogeneous solution that is light yellow to slightly orange in appearance.

Advantageously, anisole is non-toxic and environmentally acceptable. Handling of anisole is preferable to and less dangerous than NMP, DMF, DMSO or DMAC.

The at least one diamine can be selected from the group consisting of: 4,4′(Hexafluoroisopropylidene)bis[(4-aminophenoxy)benzene]; 4,4′-(Hexafluoroisopropylidene) dianiline; 3,3′-(Hexafluoroisopropylidene)dianiline; 4,4′-Diamino-2,2′-bis(trifluoromethyl)biphenyl; 1,4-Bis(4-amino-2-trifluoromethylphenoxy)benzene; 4,4′-Diaminooctafluorobiphenyl; 2,3,5,6-Tetrafluoro-1,4-phenylenediamine; 2,4,5,6-Tetrafluoro-1,3-phenylenediamine, bis(3-aminophenyl)sulfone; 1,4-bis(4-aminophenoxy)benzene; 4,4′-bis(4-aminophenoxy)biphenyl; bis[4-(4-aminophenoxy)phenyl]sulphone; 4,4′-diaminodiphenyl ether; and combinations thereof.

In certain embodiments, the at least one diamine has a structure selected from the group consisting of:

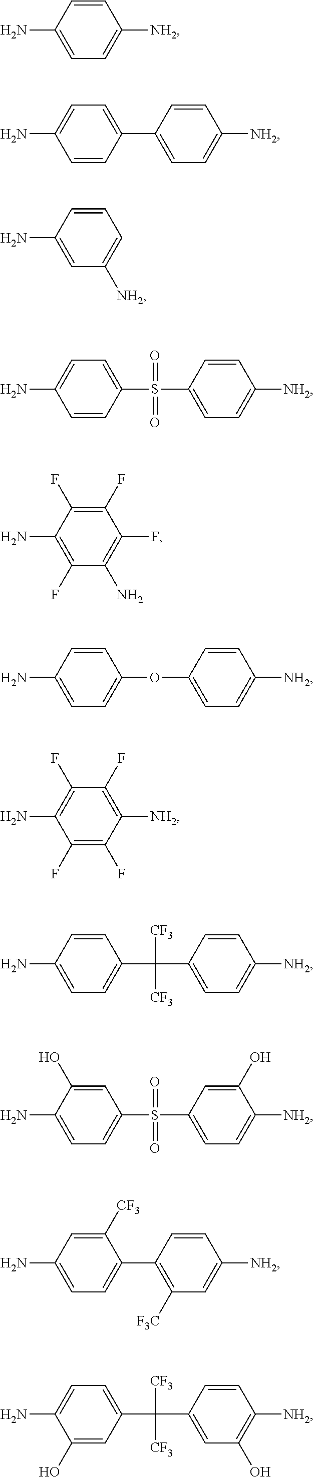

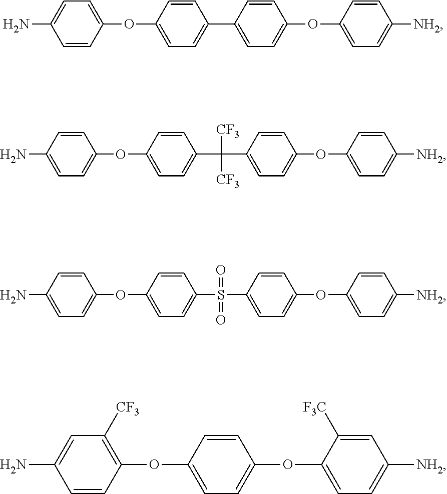 [SMILES: Nc1ccc(Oc2ccc(-c3ccc(Oc4ccc(N)cc4)cc3)cc2)cc1 ; Nc1ccc(Oc2ccc(C(c3ccc(Oc4ccc(N)cc4)cc3)(C(F)(F)F)C(F)(F)F)cc2)cc1 ; Nc1ccc(Oc2ccc(S(=O)(=O)c3ccc(Oc4ccc(N)cc4)cc3)cc2)cc1 ; Nc1ccc(Oc2ccc(Oc3ccc(N)cc3C(F)(F)F)cc2)c(C(F)(F)F)c1]

and combinations thereof.

The at least one dianhydride can be selected from the group consisting of: Pyromellitic Dianhydride; Diphenyl-3,3′,4,4′-tetracarboxylic Dianhydride; 4,4′-(Hexafluoroisopropylidene) diphthalic Anhydride; 2,3,6,7-Naphthalenetetracarboxylic 2,3,6,7-Dianhydride; Diphenyl-2,3,3′,4′-tetracarboxylic Dianhydride and combinations thereof.

In certain embodiments, the at least one dianhydride has a structure selected from the group of consisting of:

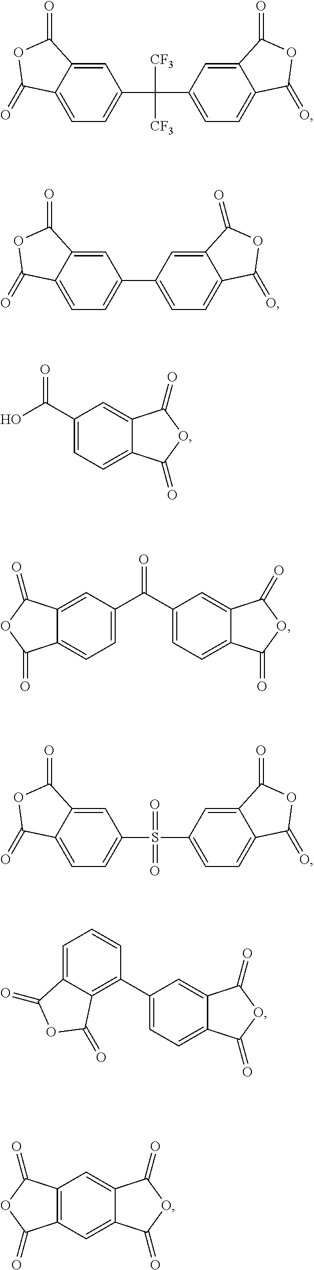

and combinations thereof.

In some aspects of the invention, one or more mono-anhydride can be mixed with or substituted for the at least one dianhydride to control the size of the polyimide. Inclusion of a mono-ahydride terminates the polyimide, thus yielding polyimide product of shorter length and lower molecular weight.

In certain embodiments of the invention, the terminal group X functionalizes the polyimides of the invention such that the compound is reactive with other molecules. As used herein, terms “functionalize”, “functionalized” and “functionalization” refer to a structural change imparted by the addition or inclusion of a moiety (a “functional moiety” or a “functional group”) to a molecule that imparts a specific property, often the ability of the functional group to react with other molecules in a predictable and/or controllable way. In certain embodiments of the invention, functionalization is imparted to a terminus of the molecule through the addition or inclusion of a terminal group, X. In other embodiments, internal and/or pendant functionalization can be included in the polyimides of the invention. In some aspects, the functional group is a “curable group” or “curable moiety”, which is a group or moiety that allows the molecule to undergo a chemical and/or physical change such that the original molecule is transformed into a solid, substantially non-flowing material. “Curable groups” or “curable moieties” may facilitate crosslinking.

The following are non-limiting examples of terminal “X” groups contemplated for use in the practice of the invention:

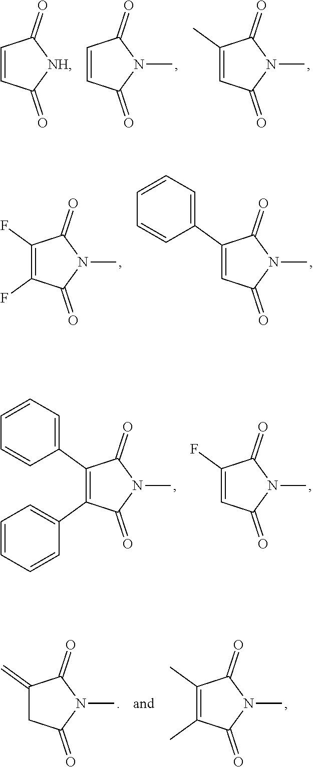

Exemplary bis-terminated polyimides of the invention include:

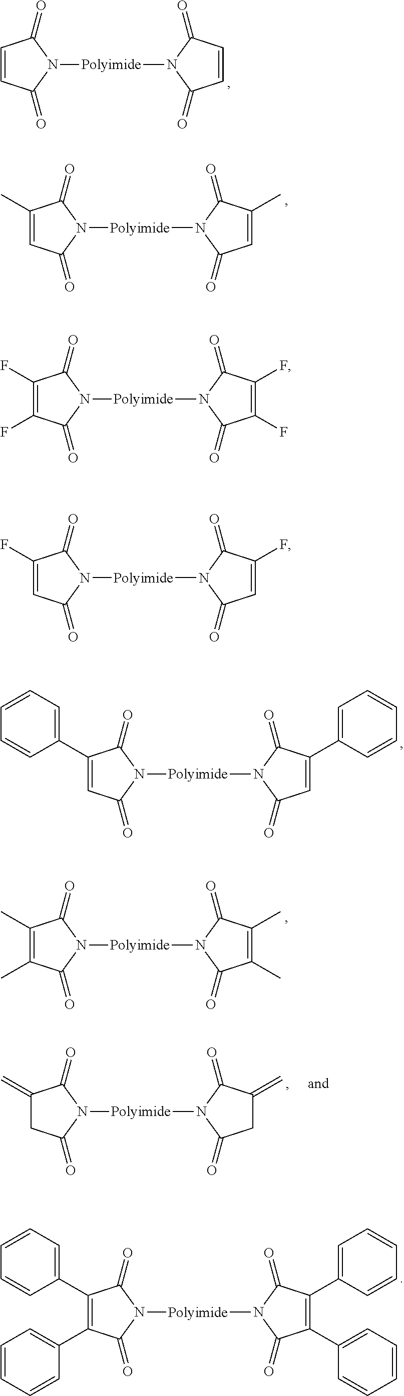

where the polyimide portion is represented by the structural Formula II:

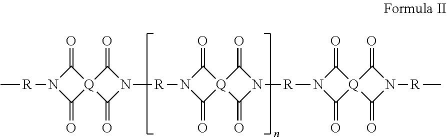

where R, Q and n are as described herein for Formula I.

The following are non-limiting examples of benzoxazine terminal X groups contemplated for polyimides of the invention:

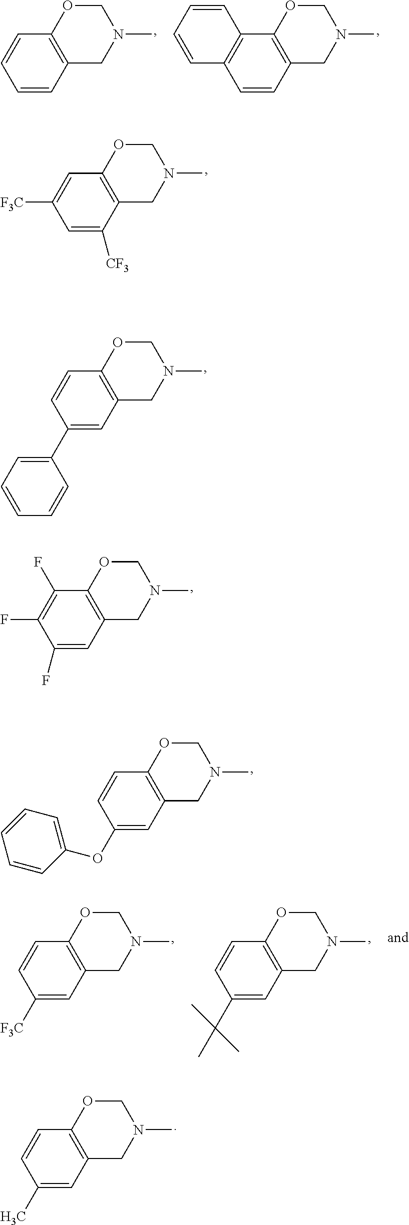

Exemplary bis-benzoxazine polyimides of the invention include:

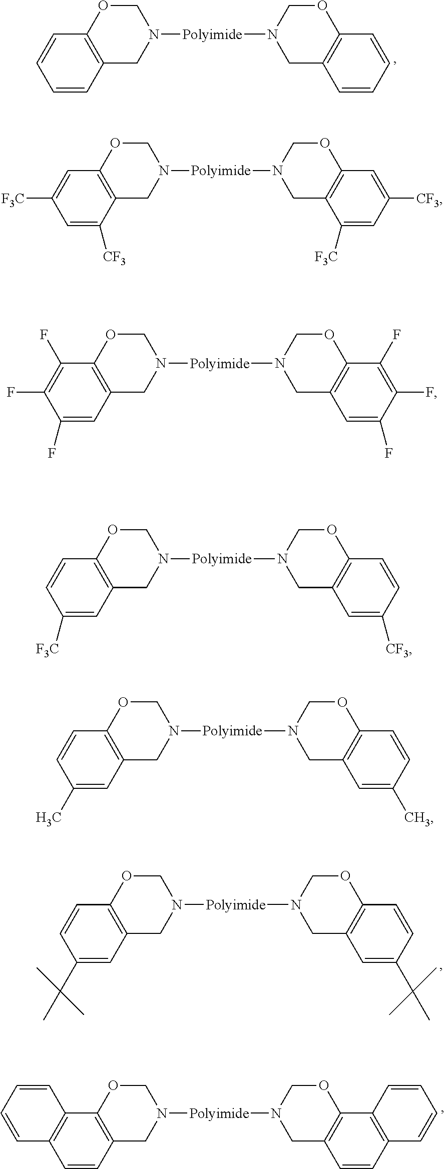

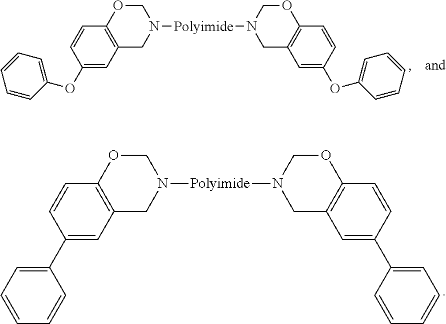

In other embodiments of the invention, one or more different, terminal functional groups are included in the polyimides of the invention. For example, polyimides can include a benzoxazine terminal group, a maleimide terminal group, or combinations and mixtures of terminal groups at stoichiometric proportions to promote subsequent reactivity at a desired rate or ratio.

In certain embodiments, suitable starting diamines and dianhydrides used in the practice of the invention are colorless or have minimal color. In certain aspects, the starting diamines and dianhydrides are substantially transparent. For example, the starting diamines and dianhydrides typically transmit at least about 90%, frequently at least about 95%, often at least about 98%, more often at least about 99%, and in certain aspects, up to about 100% visible light.

In another embodiment, the curable polyimides of the invention contain no oxidizable linkages or bonds. In one aspect, the polyimides of the invention do not include tertiary, secondary, primary or benzylic hydrogens, which readily oxidize, in the backbone. In other aspects of the invention, less than 5%, less than 4%, less than 3%, less than 2% or less than 1% or 0% of the bonds are oxidizable under conditions of exposure to oxygen and temperatures in excess of 250° C. for extended times of at least about 24 hours, at least about 100 hours, at least about 1,000 hours, at least about 2,000 hours or at least about 4,000 hours.

In another embodiment, the invention provides colorless, substantially colorless, minimally colored or tinted encapsulants and coatings. Such encapsulants and coatings include LED encapsulants and coatings comprising curable polyimides disclosed herein. In certain aspects, the LED encapsulants do not change color following exposure to light or heat. When observed, a change in color, particularly darkening during exposure to heat or light, can be an indication of decomposition. In particular aspects, the LED encapsulants are stable and do not substantially decompose at temperatures of ≥250° C., ≥300° C., ≥350° C., ≥400° C., ≥450° C., ≥500° C., or higher temperatures. Stability at such high temperatures is observed for extended times such as at least about 1 hour, at least about 10 hours, at least about 100 hours, at least about 1,000 hours, at least about 10,000 hours or at least as long as the expected lifespan of an LED. In certain aspects, the LED encapsulants show less than 10%, less than 9%, less than 8%, less than 7%, less than 6%, less than 5%, less than 4%, less than 3%, less than 2%, less than 1% color change at high temperatures, as measured spectrophotometrically.

The invention also provides methods for coating or encapsulating an LED comprising the steps of applying a composition comprising at least one polyimide disclosed herein, and curing the composition. Applying can be achieved by any method known in the art, such as by painting, spraying or spin-coating the composition on the LED, or immersing the LED in a solution of the composition. Alternatively, the LED coating can be in the form of an uncured, flexible film that is applied to the LED and then cured in place. In certain embodiments, a single application is sufficient to coat, encapsulate, protect and occlude the LED from external environmental conditions. In other embodiments, additional applications can be made to provide a thicker layer of coating or encapsulant, by repeating the application and curing step.

The invention also provides protective covers and lenses for LEDs, comprising a cured layer, shell or form fashioned from a composition including at least one polyimide disclosed herein. Such protective covers and lenses can be manufactured by any suitable method, such as by forming or molding (e.g., injection molding), followed by curing. Advantageously, protective covers and lenses can be replaced if necessitated by e.g., damage. Moreover, replaceable lenses are suitable for protecting LEDs that have a longer working life than the cured polyimide.

While darkening at elevated temperatures can be an indication of polyimide degradation, certain polyimides provided by the invention darken at high temperature, yet demonstrate excellent high temperature stability. For example, both Compound 5 and Compound 6 turn black after 24 hours at 250° C. (see FIGS. 7B and 8B) but have Td (5%) values in air above 400° C. (Table 9).

For applications where light transmittance and coloration are vital, colorless thermo-oxidation resistant polyimides of the invention are used “as is”, without additional formulation additives or co-reactants that could introduce tertiary, secondary, primary or benzylic hydrogens, which readily oxidize and thereby decrease stability. However, light transmission and colorlessness are not required in many applications requiring thermo-oxidative-resistance. Compositions and formulations of the invention containing one or more thermo-oxidation resistant compounds of Formula I, (including those that darken at high temperature), in combination with coupling agents, fillers, co-reactants, and combination thereof, can be used in a variety of high temperature, high performance application.

Advantageously, curable polyimides are characterized by dielectric constants of less than 2.7 and dielectric dissipation factor of less than 0.005. Thus, the invention provides insulating compounds, compositions, dielectric layers and films, and methods for producing prepregs, copper clad laminates and flexible copper-clad laminates. Since extreme high temperature are not generally an issue for copper clad laminates, co-reactants such as bismaleimides, epoxy resins, benzoxazines, fillers, coupling agents and catalysts. can be included in the compositions and formulation used in the process of making CCL and FCCL.

Reactive compounds that can be used in compositions and formulations of compounds while preserving the thermo-oxidative resistance of the inherent in the compound of Formula I include aromatic bismaleimide resins, aromatic benzoxazine resins, aromatic epoxy resins, and similar reactive compounds that contain substantially no heat-labile, oxidizable bonds.

In certain applications adhesion promoters and coupling agents, may be required to obtain optimum adhesion to certain surfaces. Silane coupling agents are contemplated for use in the practice of the invention.

Bismaleimide containing compounds according to Formula I, such as bis-maleimides, can be cured free-radically by the addition of peroxide generating catalysts, which are contemplated for use in the practice of the invention.

Benzoxazine-containing compounds can be self-curing by the application of heat (e.g., at 200-250 C). Certain acidic compounds (e.g., Lewis acids such as tris(pentafluorophenyl)borane, phenylboronic acid, dibutyl tin dilaurate, and zinc octoate) are known to increase the rate of polymerization of benzoxazines, which can be included in formulations and compositions containing benzoxazine-polyimide compounds of the invention.

Fillers can also be added to the invention formulations to enhance properties such as reduction of CTE and Dk. Fillers contemplated for incorporation into compositions include silica, perfluorotetraethylene (Teflon™), alumina, graphite, silver, copper and its alloys, and boron nitride.

### Prepregs, Copper-Clad Laminates and Printed Circuit Boards

The present invention also provides compositions and methods for making prepregs (reinforcement fiber pre-impregnated with a resin), copper clad laminates and printed circuit boards. Also provided are prepregs, copper-clad laminates and printed circuit boards comprising polyimides of the invention.

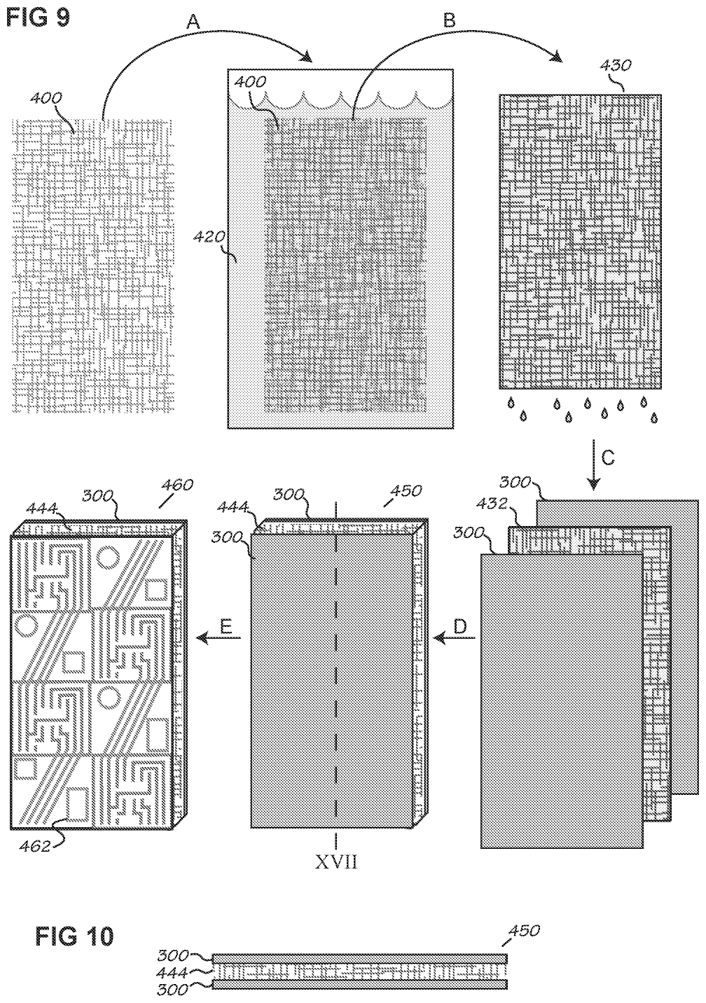

The process for preparing prepregs, copper clad laminates and printed circuit boards is illustrated in FIG. 9. Steps in the process are indicate by arrows. The process begins with a reinforcing fiber 400 such as, fiberglass or carbon fiber. The fiber can be in the form of a woven or unwoven fabric, or single strands of fiber that will be held together by the polymer. The fiber 400 is immersed in a liquid formulation 420 containing an uncured polyimide compound or composition described herein (step A), thereby impregnating the fiber with the polyimide formulation to form a prepreg. The wet prepreg 430 is then drained and dried to remove excess solvent (step B). Conveniently, the dried prepreg 432 can then be stored until needed.

The dried prepreg will typically be coated on one or both side with a layer of copper to form a copper-clad laminate (CCL). The copper can be applied by electroplating or by laminating thin copper foil to the prepreg. FIG. 9 illustrates preparation of a double-sided copper-clad laminate using copper foil 300. Thus. in step C, the dried prepreg 432 is assembled in a sandwich fashion with a sheet of copper foil 300 on either side. Optionally, layers of adhesive can be interleaved between the foil to increase adhesion (not shown). This is likely unnecessary because polyimides of the invention have strong adhesive properties. In some embodiments, adhesion promoters can be added to formulation 420 to increase bonding of the foil to the prepreg. In step D, the foil 300 is laminated to the prepreg 432 using heat and pressure. Advantageously, polyimides of the invention can be cured using heat. FIG. 10 shows a cross section of CCL 450 having a central core of fiber-reinforced, cured polyimide 444, laminated to copper foil 300 on each side.

Circuit patterns 462 can then be formed on either or both sides (double-sided CCL) of the CCL 450 by photolithography to from a printed circuit board (PCB). 460. The resulting PCB exhibits the high structural strength and very high thermo-oxidative resistance necessary for contemporary electronics applications.

### Flexible Copper-Clad Laminates

The compounds and compositions of the invention are useful in any application that requires high temperature stability and flexibility. In particular, flexible copper clad laminates (FCCLs) are increasingly used in electronics as they can provide the ultrathin thin profile demanded by increasing miniaturization. Moreover, circuitry is becoming prevalent in non-traditional situations, such as clothing, where the ability to conform to a three-dimensional shape other than a flat board is required.

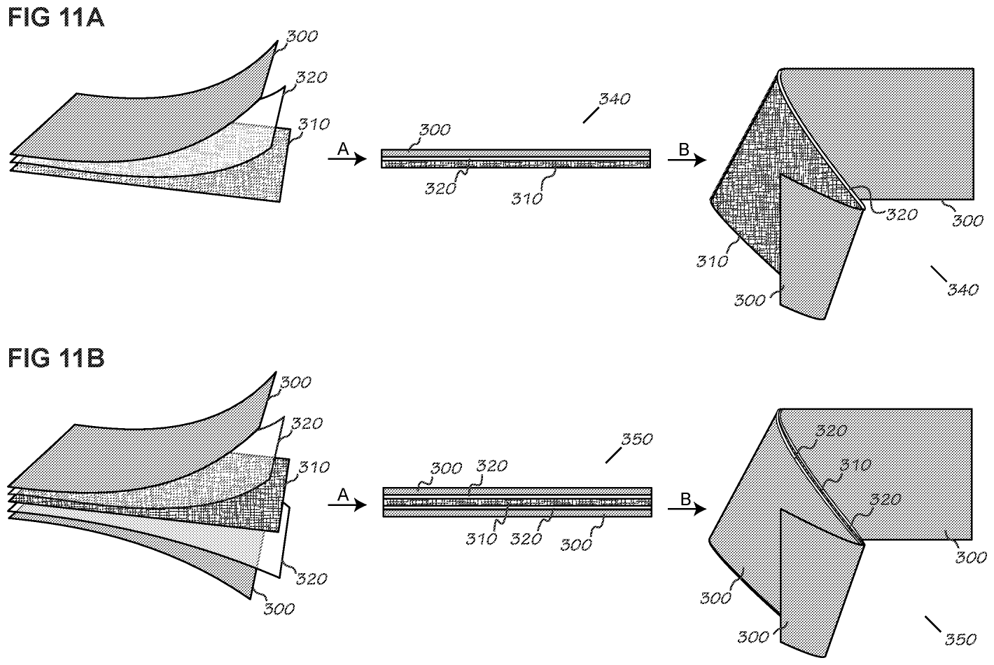

A process of forming FCCLs according to one embodiment of the invention is illustrated in FIGS. 11A and 11B for single- and double-sided FCCLs, respectively. The process is similar to preparing a prepreg-based CCL but is much thinner and lacks the rigidity of a prepreg. A thin and flexible film of polyimide polymer 310 prepared as described herein, is assembled with an adhesive layer 320 and copper foil 300 (FIG. 11A). The assembly is then laminated (step A) to form a single-sided copper clad laminate 340. The FCCL can then be rolled, bent or formed as needed (step B), while providing the basis for thin, flexible circuitry that can be used in consumer electronics, clothing and other goods.

Double-sided FCCL production according to one embodiment of the invention, is illustrated in FIG. 11B. This process is identical to that illustrated in FIG. 11A, except that the adhesive layer 320 and copper foil 300 are placed on both sides of polymer film 310 to form a 5-layer assembly, which is then laminated (step A) to form a double-sided FCCL 350.

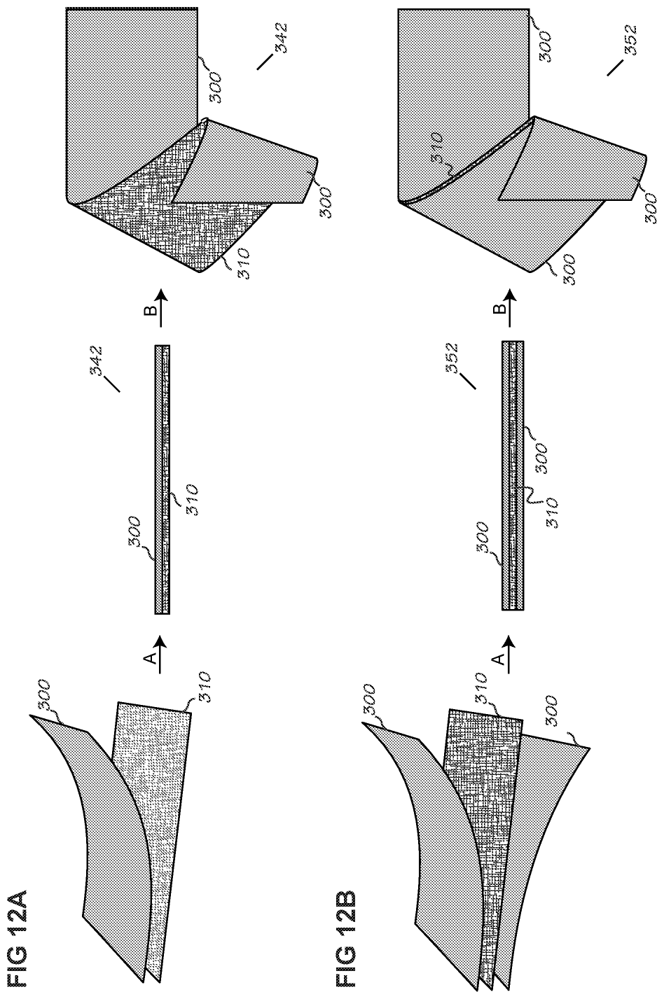

In another embodiment of the invention, adhesiveless processes for producing FCCL are provided as shown in FIGS. 12A and 12B. Single-sided FCCL (FIG. 12A) is prepared by contacting copper foil 300 with one side of a polyimide film 310 prepared as described herein. The film is then heat-cured (step A), onto the foil to form an adhesiveless FCCL 342, which is thinner and more flexible than FCCL that includes an extra layer (i.e., the adhesive layer). The single-sided, adhesiveless FCCL 342 can be rolled, bent, or formed into a desired shape before (step B) or after patterning (not shown).

Double-sided, adhesiveless FCCL can be prepared (FIG. 12B) in the same manner as the single-sided product, except that both sides of film 310 are contacted with foil 300 prior to curing (step B). The double-sided adhesiveless FCCL 352 according to this embodiment of the invention can similarly be rolled, shaped, and formed (step B).

In yet another FCCL embodiment of the invention eliminates the step of forming a polymer film prior to assembly. Instead, a liquid formulation of the polymer is applied directly to the copper foil. Application can be by any method known in the art, such as by pouring, dropping, brushing, rolling or spraying, followed by drying and heat-curing. To prepare a double sided FCCL according to this embodiment of the invention, polymer-coated foil is prepared, dried and then a second foil is contacted on the polymer side of the foil prior to curing.

Application of circuit traces to FCCL can be performed using standard photolithography processes developed for patterning printed circuit boards.

### EXAMPLES

### Materials and Methods

### Dynamic Mechanical Analysis (DMA)

Polymer formulations were prepared in a suitable solvent (e.g. anisole) and dispensed into a to 5-inch×5-inch stainless steel mold. The mixture was then vacuum degassing and the solvent (e.g. anisole) was allowed to slowly evaporate at 100° C. for ˜16 hours in an oven. The oven temperature was then ramped to 200° C. and held for 1 hour for curing, before cooling to room temperature. The resulting film (500±300 μm) was then released from mold and cut into strips (6±1 mm×23+1 mm) for measurement.

The strips were analyzed on a Rheometrics Solids Analyzer (RSA ii) (Rheometric Scientific Inc.; Piscataway, N.J.) with a temperature ramp from 25 to 250° C. at a rate of 10° C./min under forced air using the Dynamic Temperature Ramp type test with a frequency of 6.28 rad/s. The autotension sensitivity was 1.0 g with max autotension displacement of 3.0 mm and max autotension rate of 0.01 mm/s. During the test, maximum allowed Force was 900.0×g and min allowed force is 3.0×g. Storage modulus and loss modulus temperature were plotted against and temperature. The maximum loss modulus value found was defined as the glass transition (T_{g}).

T_{g} (glass transition temperature) and modulus were measure with cured film by Rheometrics solid analyzer RSA-II and tensile mode. Film dimension was width 6+/−1 mm×length 23+/−1 mm×thickness 0.5+/−0.3 mm and measuring temperature was from 10° C. to 250C with 5° C./min heating rate.

T_{g}, modulus, and CTE were to predict mechanical stability of dielectric material (polymer film) in various range of operating temperature.

### COEFFICIENT of Thermal Expansion (CTE)

Formulations were prepared as above for DMA. Samples sufficient to give a 0.2 mm to 10 mm thick film were dried at 100° C. for 2 hours to overnight and cured for 1-2 hours at ˜180° C. to ˜250° C.

CTE was measure with cured film by Hitachi TMA-7000 expansion mode from 25° C. to 250° C. with 10° C./min heating rate.

Hitachi TMA7100 was used for CTE measurement. The film was placed on the top of a sample holder (disk type quartz) and move down quartz testing probe was lowered onto top of the sample to measure sample thickness. The temperature ramped from 25° C. to 250° C. at a 5° C./min, load 10 mN to measure expansion/compression. CTE was calculated as the slope of length change verses temperature change in ppm/° C. α1 CTE and α2 CTE were calculated based on T_{g}.

### Thermalgravimetric Analysis (TGA)

Thermalgravimetric analysis measurements were performed on an TGA-50 Analyzer (Shimadzu Corporation; Kyoto, Japan) under an air flow of 40 mL/min with heating rate of 5° C./min to or 10° C./min to 505° C. The sample mass lost versus temperature change was recorded and the decomposition temperature (Td (5%) air) was defined at the temperature at which the sample lost 5% of its original mass.

### Tensile Strength and Percent Elongation

Samples were dried to remove solvent at 100° C. for 2 hours to overnight and cured for 1-2 hours at 180° C.˜250° C. in a metal mold to obtain thin films. Test strip film dimension for test was 6 inch×0.5 inch×0.25 inch; measurement length 4.5 inches.

The tensile strength and percent elongation were measure using an Instron 4301 Compression Tension Tensile Tester. Tensile strength was calculated as the ratio of load verses sample cross-section area (width×thickness). Percent elongation was calculated as the ratio of original length of sample (4.5 inch) verses length at break point.

### Permittivity/Dielectric Constant (Dk) and Loss Tangent/Dielectric Dissipation Factor (Df)

Formulations were prepared as above for DMA. Dk and Df were measured using a AET Anritsu tester at 20 GHz frequency to determine dielectric properties of cured film (30 mm×30 mm×less than 300 μm thickness). For 5G application, Dk and Df value are very critical to determine performance of electrical devices. The lower the dissipation factor (Df), the more efficient is the insulator system.

### Flammability

Five specimens 5″×½″ (12.7 cm×1.27 cm)×(0.3 mm thickness) of each material were flame ignited, with dry absorbent surgical cotton located 300 mm below the test specimen (drip test for flaming particles) and rated according the specifications summarized in Table 1 below.

TABLE 1
UL94 Standard Flammability Ratings

| Classification | Test |
|---|---|
| HB | slow burning on a horizontal specimen; |
| | burning rate <76 mm/min for |
| | thickness <3 mm or burning stops before 100 mm |
| V-2 | burning stops within 30 seconds |
| | on a vertical specimen; drips of |
| | flaming particles are allowed. |
| V-1 | burning stops within 30 seconds |
| | on a vertical specimen; drips of |
| | particles allowed as long as they are not inflamed. |
| V-0 | burning stops within 10 seconds |
| | on a vertical specimen; drips of |
| | particles allowed as long as they are not inflamed |
| 5VB | burning stops within 60 seconds |
| | on a vertical specimen; no drips |
| | allowed; plaque specimens may develop a hole. |
| 5VA | burning stops within 60 seconds |
| | on a vertical specimen; no drips |
| | allowed; plaque specimens may not develop a hole |

### UV/Visible Spectrophotometry

Measurements were carried out by Sekisui Chemical Co., Ltd. (Osaka, Japan). A 20% solids solution of polyimide in anisole was cast into a film on a polyethylene terephthalate backing film using a fixed thickness precision film applicator (doctor blade) set to 10 microns thickness. The film was dried was dried in an oven for 20 minutes at 120° C. to remove the solvent to produce a coat and dry film. Approximately half of the coat and dry film was placed in an oven for an additional 2 hours at 300° C. to fully cure the sample, producing a cured film.

The coat and dry film and the cured film were each placed between two glass plates (control reference sample of ethanol between two glass plates), and analyzed using a Hitachi High-technologies Model U-3900 UV-visible Double-Beam Spectrophotometer (Hitachi Global, Tokyo, JP) for % transmittance of light in the UV (≤400 nm) and visible (>400-900 nm) and the results plotted as % transmittance vs wavelength.

### Gel Permeation Chromatography

Gel permeation chromatography analysis of polymer molecular weight was carried out on an Ultimate 3000 HPLC instrument (Thermo Scientific; Carlsbad, Calif.) using tetrahydrofuran (THF) as eluent solvent and polystyrene standards as reference for molecular weight (MW) calculation based on the retention time of the polymer samples. The standards used had MWs of: 96,000; 77,100; 58,900; 35,400; 25,700; 12,500; 9,880; 6,140; 1,920; 953; 725; 570; 360; and 162. UV-vis detecting mode was applied at wavelength 220 nm and 10 mg/mL polymer in THF solution were used for testing.

### Chemicals

Unless another supplier is indicated, chemicals were purchased from TCI America, Portland, Oreg.

### Example 1: Synthesis of Benzoxazine-Terminated Polyimide, Compound 1

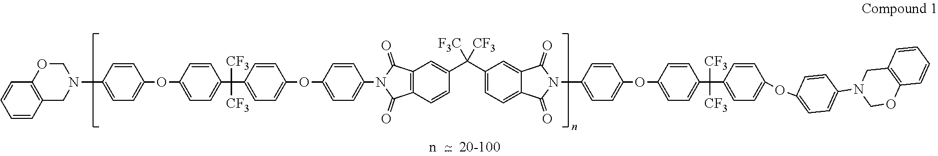

A 1 L round-bottomed flask equipped with a Teflon™ (polytetrafluoroethylene; PTFE)-coated stir bar and Dean-Stark trap was charged with 54.4 g (105 mmol) of 2,2-Bis[4-(4-aminophenoxy)phenyl]hexafluoropropane (F6-Diamine) (Wilshire Technologies; Princeton, N.J.) along with 300 g of anisole. The solution was stirred and 44.4 g (100 mmol) of 4,4′-(hexafluoroisopropylidene)diphthalic anhydride (Wilshire Technologies) was added to the flask. The mixture was stirred and slowly heated to 130° C. to dissolve all the solids to form a polyamic acid. The solution was then heated to reflux for 1 hour to completely remove water generated during the synthesis and form an amine-terminated polyimide. The light-yellow colored solution was cooled to room temperature followed by the addition of 1.0 g of paraformaldehyde (TCI America) and 1.03 g (11 mmol) of phenol (TCI America) with 100 g of toluene (Gallade Chemicals; Escondido, Calif.). The solution was heated again to reflux for about 1 hour to complete benzoxazine formation with the azeotropic removal of water, and excess formaldehyde and phenol. The toluene was also removed by rotary evaporation.

Characterization of Product: ¹H NMR (CDCl₃) δ 4.61 (s, faint benzoxazine), 5.33 (s, faint benzoxazine), 7.05 (d, 4H), 7.19 (d, 4H), 7.42 (m, 8H), 7.90 (d, 2H), 7.94 (d, 2H), 8.05 (d, 2H). ¹³C NMR (CDCl₃) d 118.5, 124.4, 125.6, 127.0, 128.5, 132.1, 132.6, 132.9, 136.2, 156.4, 157.6, 159.8, 166.2, 166.3. Fourier-transform infrared spectroscopy (FTIR): vₘₐₓ 1722, 1500, 1375, 1238, 1170, 1110, 827, 720, 510.

Additional properties of Compound 1 are summarized below in Table 2.

TABLE 2
Properties of Benzoxazine-Terminated Polyimide, Compound 1

| Property | Value |
|---|---|
| CTE | 32 ppm/° C. |
| T_{g} (DMA) | 203° C. |
| Modulus @25° C., | 1.5 GPa |
| Dk @20 GHz | 2.4, |
| Df @20 GHz | 0.0038 |
| Td (5%) Air | 504° C. |
| Flammability UL 94 | V0 |
| Average MW (Daltons) | ~86,000 ± 10,000 |

The product was maintained as a solution in anisole for casting into thin films. In certain applications, the product was isolated by precipitation with methanol.

A solution of the product in anisole was cast into thin film by removal of the anisole in a staged oven. Briefly, the solution was vacuum degassing and the solvent was allowed to slowly evaporate at 100° C. for ˜16 hours in the oven. Thermal curing: the oven temperature was then ramped to 180° C. and held for 1 hour, followed by ramping to 200° C. and holding for 1 hour before cooling to room temperature. The final cured film (approximately 200-300 μm thick) was a light-yellow plastic.

Thermal Aging. Compound 1 is a polyimide with a fluorinated backbone polyimide and benzoxazine terminal groups. The C—F bonds in the Compound 1 backbone are not easily oxidized, and thus this compound was expected to be have high thermo-oxidative stability.

250° C. Long-Term Aging. The polyimide was aged at 250° C. for 2,000 hours with little change in color from light yellow to darker shade of yellow, and very little change in mass: initially about 3% change in mass was observed due to residual solvent. Thereafter 0% change was observed, demonstrating resistance to thermo-oxidative degradation.

Aging at 400° C. A sample of Compound 1 dried film was placed in a TGA pan and the temperature was ramped 50° C. per min to 400° C., and then held for 1 hour 400° C. Final weight loss over 1 hour at 400° C. was 3.41%.

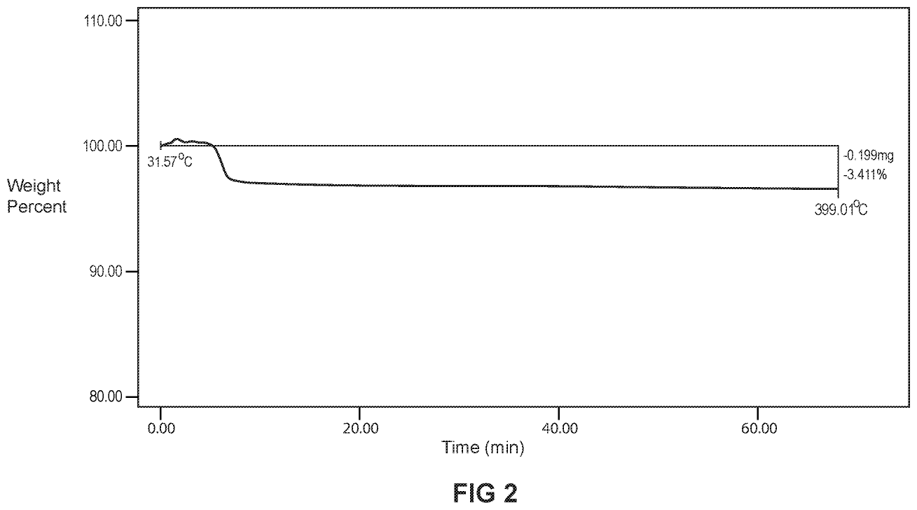

An initial weight loss was observed during the ramp-up stage (see FIG. 2), which is suspected to be due to residual solvent evaporation and/or thermo-oxidative degradation of the terminal benzoxazine groups, however after that there is virtually no further weight loss. The same result was observed during a long term aging study (4,000 hours at 250° C.), during which the film was found to darken slightly from a light yellow to a darker shade of yellow within the first hour or so at 250° C., but thereafter, the material was very stable and did not change over 4,000 hours at 250° C. (data not shown).

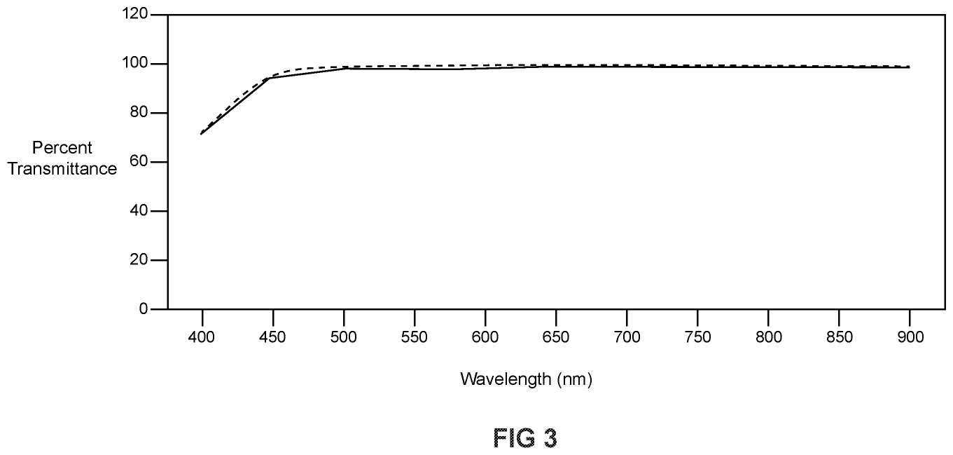

Light Transmittance. A thin film (10 microns thick) of the polyimide was analyzed using a Hitachi High-technologies U-3900 spectrophotometer for light transmittance. The analysis showed that in the UV range the material completely blocks the transmittance of light due to its aromatic nature (FIG. 3). However, in the visible range the material showed >98% light transmittance (FIG. 3). These data confirmed the suitability of materials containing the polyimide for LED coatings and other applications in which resistance to thermo-oxidative degradation is required.

The combination of UV blocking and visible light transmittance make the benzoxazine-terminated polyimide, Compound 1, uniquely suited to certain coatings and window films, where it is desirable to have visible light streaming into interior spaces, while blocking UV light due to the cancer-causing and furniture fading properties of light in the UV spectrum.

### Example 2: Synthesis of Compound 2

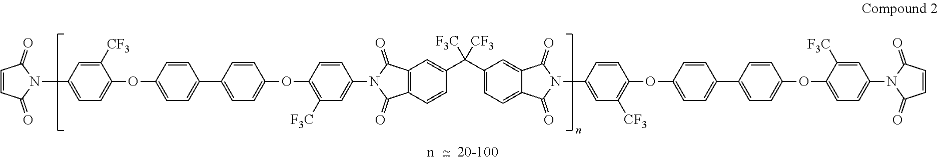

A 250 mL round-bottomed flask was charged with 10.6 g (21.0 mmol) of 4,4-bis(4-amino-2-trifluoromethylphenoxy) biphenyl (Akron Polymer Systems; Akron. Ohio) and 150 mL of anisole. The mixture was stirred at room temperature to completely dissolve the white powder. To the flask was added 8.9 g (20.0 mmol) of 4,4′-(hexafluoroisopropylidene)diphthalic anhydride (6-FDA) (Wilshire Technologies), and the mixture was stirred at room temperature until homogeneous. The solution was heated to reflux at 155° C. for 1 hour to complete the synthesis of an amine-terminated polyimide. The solution was cooled to below 50° C., followed by the addition of 0.24 g (2.4 mmol) of maleic anhydride (Millipore Sigma; Burlington, Mass.) and 1.0 g of Amberlyst® 36 resin (polymer bound sulfonic acid catalyst; Dow Chemical, Midland, Mich.). The mixture was again refluxed for 1 hour to complete the maleimide-terminated polyimide synthesis. The Amberlyst® 36 resin was removed by filtration. Since the product was kept in anisole from synthesis to the final 25% solids, light yellow-colored solution, yield was 100%.

Characterization of Product: ¹H NMR (DMSO) δ 7.11 (t, 1H), 7.27 (m, 3H), 7.76 (m, 6H), 7.95 (m, 2H), 8.23 (m, 1H). ¹³C NMR (D MSO) δ 118.5, 121.8, 126.7, 128.3, 128.5, 129.4, 132.6, 134.8, 137.3, 154.2. 155.0, 165.6, 166.0. FTIR: vₘₐₓ 1723, 1502, 1368, 1158, 828, 518.

Additional properties of Compound 2 are summarized below in Table 3.

TABLE 3
Properties of Compound 2

| Property | Value |
|---|---|
| CTE | 28 ppm/° C. |
| T_{g} (DMA) | 230° C. |
| Modulus @25° C. | 1.7 GPa |
| Dk@20 GHz | 2.35 |
| Df@20 GHz | 0.0038 |
| Td (5%), Air | 405° C. |
| Flammability UL 94 | V0 |
| Average MW (Daltons) | ~38,000 ± 10,000 |

### Example 3: Synthesis of Compound 3

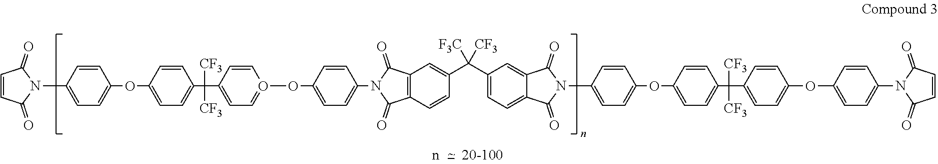

A 1 L round-bottomed flask, equipped with a Teflon™-coated stir bar and Dean-Stark trap, was charged with 105.0 mmol (54.4 g) of 2,2-Bis[4-(4-aminophenoxy)phenyl] hexafluoropropane (Wilshire Technologies) along with 300 g of anisole. The solution was stirred and 100.0 mmol (44.4 g) of 4,4′-(hexafluoroisopropylidene)diphthalic anhydride (Wilshire Technologies) was added to the flask. The mixture was stirred and slowly heated to 130° C. to dissolve the solids and form a polyamic acid. The solution was heated to reflux for 1 hour to completely remove water and form an amine-terminated polyimide. The light-yellow colored solution was cooled room temperature, followed by the addition of 1.2 g (12 mmol) of maleic anhydride along with 2.0 g of Amberlyst® 36 resin, and 100 mL of toluene. The solution was again heated to reflux for about 1 hour to complete bismaleimide formation with the azeotropic removal of water. The toluene was removed by rotary evaporation, and the material concentrated to 25% solids in anisole. A light-yellow colored solution was obtained with 100% yield of product.

Characterization of Product: ¹H NMR (CDCl₃) δ 6.83 (s, faint maleimide), 7.05 (d, 4H), 7.19 (d, 4H), 7.41 (m, 8H), 7.88 (d, 2H), 7.94 (s, 2H), 8.05 (s, 2H). 13C NMR (CDCl3) d 118.5, 124.4, 125.5, 127.0, 131.9, 132.5, 132.8, 134.4, 136.1, 139.4, 156.3, 157.5, 166.1, 166.3. FTIR: vₘₐₓ 1722, 1500, 1375, 1238, 1170, 1110, 827, 720, 510.

Additional properties of Compound 3 are summarized below in Table 4.

TABLE 4
Properties of Compound 3

| Property | Value |
|---|---|
| CTE | 28 ppm/° C. |
| T_{g} (DMA) | 220° C. |
| Modulus @25° C. | 1.75 GPa |
| Dk@20 GHz | 2.42 |
| Df@20 GHz | 0.0040 |
| Td (5%), Air | 410° C. |
| Flammability UL 94 | V0 |
| Average MW (Daltons) | ~87,000 ± 10,000 |

### Example 4: Synthesis of Compound 4

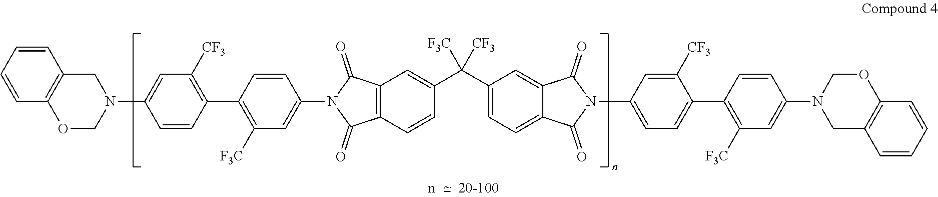

A 250 mL round bottomed flask was charged with 6.8 g (21.0 mmol) of 2,2′-bis(trifluoromethyl)benzidine (Akron Polymer Systems, Akron, Ohio) along with 150 mL of anisole. The mixture was stirred at room temperature to completely dissolve the white powder. To the flask was added 8.9 g (20.0 mmol) of 6-FDA, and the Mixture was Stirred at Room Temperature Until Homogeneous. The solution was heated to reflux at 155° C. for 1 hour to complete the synthesis of an amine-terminated polyimide. The solution was cooled to below 80° C., followed by the addition of 0.23 g (2.4 mmol) of phenol and 0.18 g (6.0 mmol) of paraformaldehyde. The mixture was again refluxed for 1 hour to complete the benzoxazine-terminated polyimide synthesis, producing a very faint yellow solution of the product in anisole. The complete synthesis reagents and product were kept in anisole as a 25% solids solution with 100% yield.

Characterization of Product: ¹H NMR (DMSO) δ 6.93 (m, 1H), 7.30 (t, 1H), 7.70 (d, 2H), 7.86 (m, 4H), 8.02 (m, 4H), 8.29 (d, 2H). ¹³C NMR (DMSO) δ 120.4, 123.6, 124.6. 126.7, 130.6, 132.8, 136.0, 137.4, 159.2, 165.6, 165.8. FTIR: vₘₐₓ 1722, 1503, 1372, 1165, 832, 522.

Additional properties of Compound 4 are summarized below in Table 5.

TABLE 5
Properties of Compound 4

| Property | Value |
|---|---|
| CTE | 22 ppm/° C. |
| T_{g} (DMA) | 250° C. |
| Modulus @25° C. | 1.88 GPa |
| Dk@20 GHz | 2.43 |
| Df@20 GHz | 0.0030 |
| Td (5%), Air | 407° C. |
| Flammability UL 94 | V0 |
| Average MW (Daltons) | ~35,000 ± 10,000 |

### Example 5: Synthesis of Compound 5

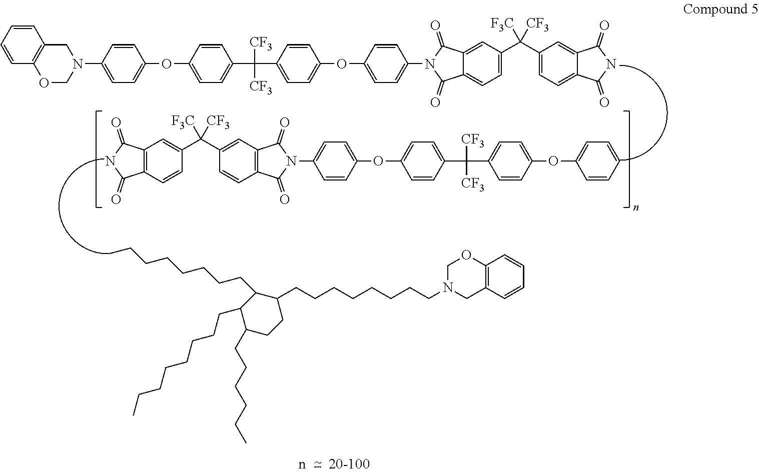

A 1 L round-bottomed flask equipped with a Teflon™-coated stir bar and Dean-Stark trap was charged with 44.1 (85 mmol) of 2,2-Bis[4-(4-aminophenoxy)phenyl] hexafluoro propane (Wilshire Technologies, Princeton N.J.), 11.0 g (20 mmol) PRIAMINE®-1075 (Croda, East Yorkshire, UK; or VERSAMINE®-552, BASF, Ludwigshafen, Germany) and 400 g anisole. The solution was stirred and 44.4 g (100 mmol) of 4,4′-(hexafluoroisopropylidene)diphthalic anhydride (Wilshire Technologies) was added to the flask. The mixture was stirred and slowly heated to 130° C. dissolve all the solids to form a polyamic acid. The solution was then heated to reflux for 1 hour to completely remove water and form an amine-terminated polyimide. The light-yellow colored solution was cooled down to room temperature followed by the addition of 0.75 g of paraformaldehyde, 0.98 g (10.4 mmol) of phenol, and 100 g of toluene. The solution was heated again to reflux for about 1 hour to complete benzoxazine formation with the azeotropic removal of water, molar excess formaldehyde and phenol. The toluene was also removed by rotary evaporation, and the material concentrated to 25% solids in anisole, with 100% yield of product.

Characterization of Product: ¹H NMR (CDCl₃) δ 0.88 (s, 2H), 1.26 (m, 10H), 1.34 (s, 2H), 4.63 (s, faint benzoxazine), 5.33 (s, faint benzoxazine), 7.06 (d, 2H), 7.20 (d, 2H), 7.44 (m, 4H), 7.79 (m, 1H), 7.89 (m, 1H), 7.95 (m, 1H), 8.06 (t, 1H). ¹³C NMR (CDCl₃) d 14.3, 22.9, 27.0, 28.7, 29.9, 32.1, 38.7, 118.5, 120.1, 123.7, 124.9, 125.6, 128.5, 133.3, 136.1, 139.5, 156.4, 157.5, 166.1, 166.3. FTIR: vₘₐₓ 1717, 1502, 1374, 1240, 1171, 1109, 828, 720, 511.

Additional properties of Compound 5 are summarized below in Table 6.

TABLE 6
Properties of Compound 5

| Property | Value |
|---|---|
| CTE | 46 ppm/° C. |
| T_{g} (DMA) | 196° C. |
| Modulus @25° C. | 1.65 GPa |
| Dk@20 GHz | 2.5 |
| Df@20 GHz | 0.0021 |
| Td (5%), Air | 443° C. |
| Flammability UL 94 | Flammable* |
| Average MW (Daltons) | ~85,000 ± 10,000 |

*due to hydrocarbon portion

### Example 6: Synthesis of Compound 6

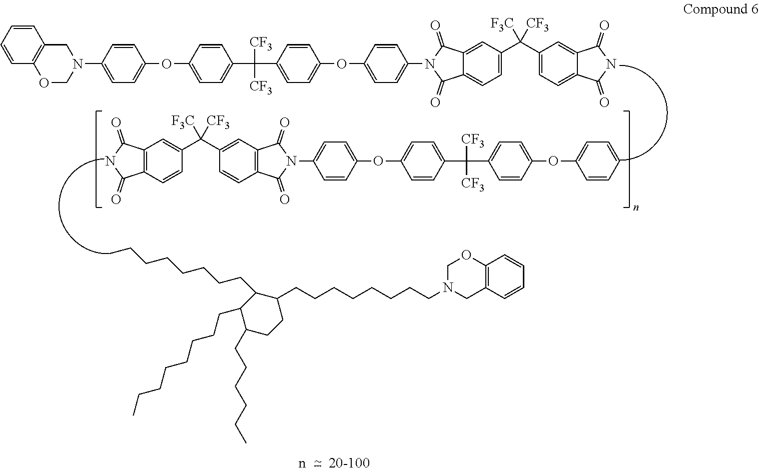

A 1 L round-bottomed flask equipped with a Teflon™-coated stir bar and Dean-Stark trap was charged with 38.8 g (75 mmol) of 2,2-Bis[4-(4-aminophenoxy)phenyl] hexafluoro propane (Wilshire Technologies, Princeton N.J.), 16.5 g (30 mmol) of Priamine®-1075 and 400 g of anisole. The solution was stirred and 44.4 g (100 mmol) of 4,4′-(hexafluoroisopropylidene)diphthalic anhydride (Wilshire Technologies) was added to the flask. The mixture was stirred and slowly heated to 130° C. to dissolve all the solids and form a polyamic acid. The solution was then heated to reflux for 1 hour to completely remove water and form an amine-terminated polyimide. The light-yellow colored solution was cooled to room temperature followed by the addition of 0.75 g of paraformaldehyde, 0.98 g (10.4 mmol) of phenol and 100 g of toluene. The solution was heated again to reflux for about 1 hour to complete benzoxazine formation with the azeotropic removal of water, excess formaldehyde and phenol. The toluene was also removed by rotary evaporation, and the material concentrated to 25% solids in anisole with 100% yield of product

Characterization of Product: ¹H NMR (CDCl₃) δ 0.88 (s, 2H), 1.26 (m, 10H), 1.34 (s, 2H), 4.63 (s, faint benzoxazine), 5.33 (s, faint benzoxazine), 7.06 (d, 2H), 7.20 (d, 2H), 7.44 (m, 4H), 7.79 (m, 1H), 7.89 (m, 1H), 7.95 (m, 1H), 8.06 (t, 1H). ¹³C NMR (CDCl₃) d 14.3, 22.9, 27.0, 28.7, 29.9, 32.1, 38.7, 118.5, 120.1, 123.7, 124.9, 125.6, 128.5, 133.3, 136.1, 139.5, 156.4, 157.5, 166.1, 166.3. FTIR: vₘₐₓ 1717, 1502, 1374, 1240, 1171, 1109, 828, 720, 511.

Additional properties of Compound 6 are summarized below in Table 7.

TABLE 7
Properties of Compound 6

| Property | Value |
|---|---|
| CTE | 69 ppm/° C. |
| T_{g} (DMA) | 176° C. |
| Modulus @25° C. | 920 MPa |
| Dk@20 GHz | 2.55 |
| Df@20 GHz | 0.00158 |
| Td (5%), Air | 412° C. |
| Flammability UL 94 | Flammable* |
| Average MW (Daltons) | ~70,000 ± 10,000 |

*due to hydrocarbon portion

Thermal Aging. Compound 6 is similar to Compound 1, however, approximately 30% of the aromatic diamine was substituted with an aliphatic diamine. This polymer contains many primary, secondary and tertiary aliphatic hydrogens and weak carbon-carbon bonds and therefore provides an important comparison for the effects of replacing 1°, 2°, and 3° hydrogen bonds with C—F bonds.

250° C. Long-Term Aging. The polyimide was aged at 250° C. for 2,000 hours described above in EXAMPLE 1. After 24 hours, the initially transparent film was entirely blackened (FIGS. 7A and 7B).

400° C. Aging. A dried sample at 250° C. was placed on a TGA pan and ramped at 50° C. per minute up to 400° C. and held for 1 hour. Final weight loss over 1 hour at 400° C. was 14.1%.

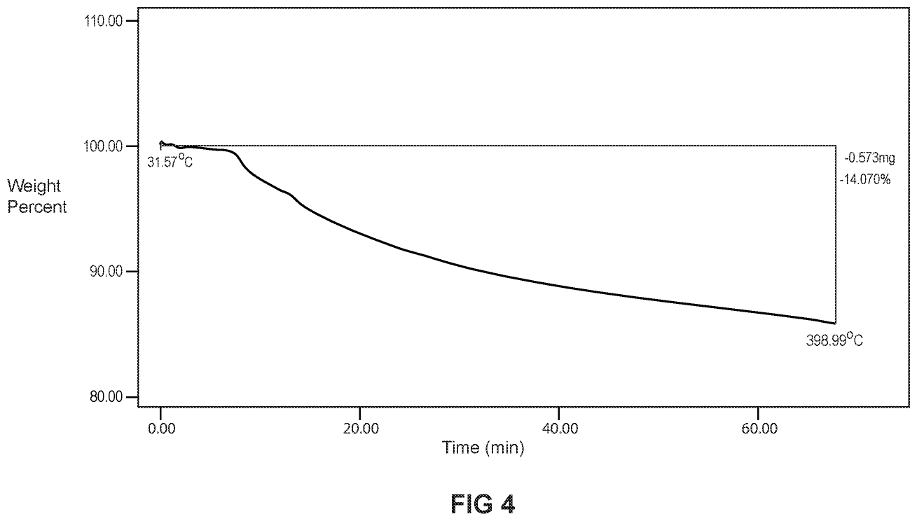

An initial weight loss attributed to residual solvent loss (similar to that seen with Compound 1) was observed (FIG. 4); however, steady weight loss occurred thereafter to produce a final charred material (FIG. 4). This material also turned black in the long-term aging study at 250° C. (see also FIGS. 7A and 7B).

### Example 7: Synthesis of Compound 7

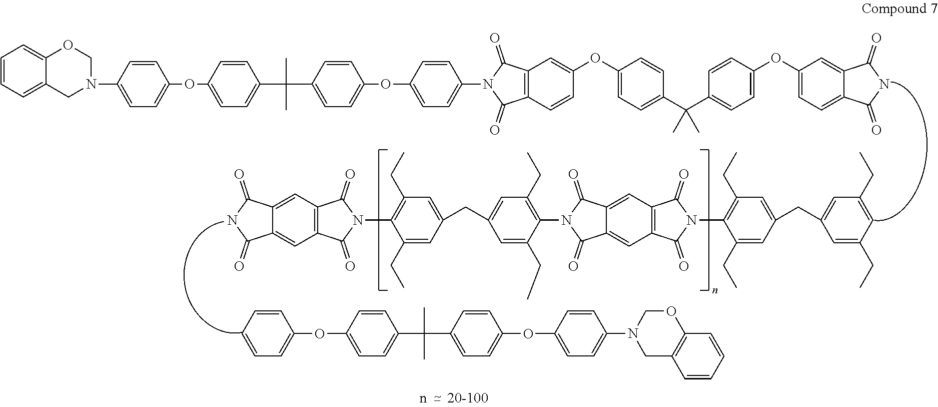

A 3 L reactor was charged with 0.90 mol (279.3 g) of 4,4′-methylenebis(2,6-diethylaniline) (Millipore Sigma, Burlington Mass.) and 1500 g of anisole. The solution was stirred while a mixture of 0.60 mol (312.0 g) of bisphenol-A-dianhydride (Millipore Sigma, Burlington, Mass.) and 0.40 mol (87.3 g) of pyromellitic dianhydride (Millipore Sigma, Burlington, Mass.) were added to the reactor. The mixture was stirred to form a dark solution, followed by heating to about 155° C. to obtain reflux, upon which the water produced during imidization was collected in a Dean-Stark trap. After approximately 2 hours the reaction was complete as no further water was generated in the reaction, thereby producing an anhydride-terminated polyimide. The solution was cooled to under 100° C., and quickly 0.15 mol (61.6 g) 2,2′-bis[4-(4-aminophenoxy)phenyl]propane (Wilshire Technologies; Princeton N.J.) was added to the reactor. The solution was heated to reflux for another hour and the water removed to produce an amine-terminated polyimide. The solution was cooled to room temperature, followed by the addition of 0.12 mol (11.3 g) of phenol, 0.29 mol (8.7 g) of paraformaldehyde, and 300 g of toluene. The mixture was again heated to reflux for 1 hour to produce a benzoxazine-terminated polyimide.

The solution was placed on a rotary evaporator and the toluene and excess anisole were removed under vacuum to product a 20% by weight solution of the product in anisole, with 100% yield of product.

Characterization of Compound 7. ¹H NMR (CDCl₃) δ 1.11 (t, 6H), 1.76 (s, 3H), 2.43 (q, 4H), 4.63 (s, faint benzoxazine), 5.33 (s, faint benzoxazine), 7.05 (d, 2H), 7.09 (s, 2H), 7.35 (m, 3H), 7.38 (dd, 1H), 7.43 (d, 1H), 7.89 (d, 1H). (FTIR): vₘₐₓ 1720, 1601, 1496, 1368, 1237, 1038, 740, 690 541.

Additional properties of Compound 7 are summarized below in Table 8.

TABLE 8
Properties of Compound 7

| Property | Value |
|---|---|
| CTE | 28 ppm/° C. |
| T_{g} (DMA) | 228C |
| Modulus @25° C. | 1,850 MPa |
| Dk@20 GHz | 2.783 |
| Df@20 GHz | 0.00789 |
| Td (5%), Air | 504° C. |
| Flammability UL 94 | V0* |
| Average MW (Daltons) | ~60,000 ± 5,000 |

*due to hydrocarbon portion

Thermal Aging. Polyimide Compound 7 has a fully aromatic polyimide backbone with terminal benzoxazine groups, containing primary, secondary and benzylic hydrogens. This aromatic polyimide was analyzed as a comparator to Compound 1 and Compound 6 that can undergo thermo-oxidative degradation at high temperature.

250° C. Long-Term Aging. The Compound 7 polyimide was aged in an oven at 250° C. for 2,000 hours as described above in EXAMPLE 1. After 24 hours, the initially transparent film (FIG. 8A) was entirely blackened (FIG. 8B).

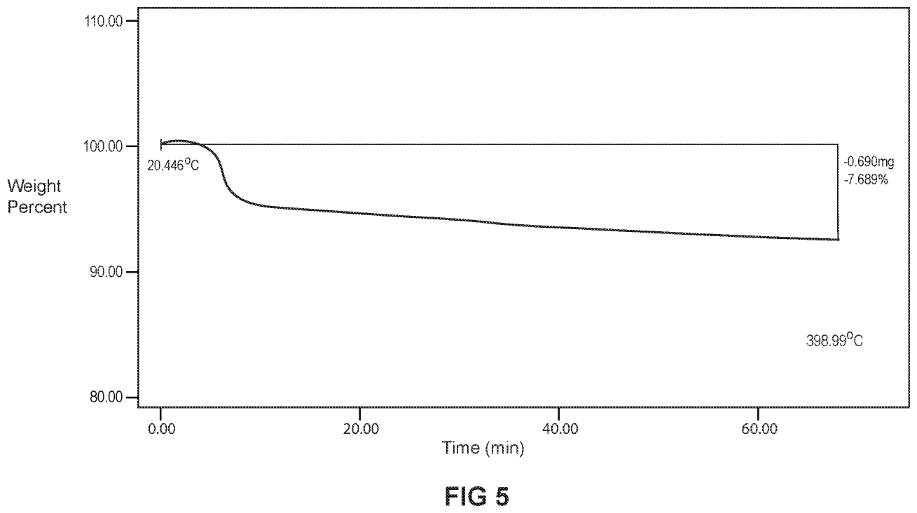

400° C. Aging. A sample of the dried film was placed on a TGA pan and the temperature was ramped at a rate of 50° C. per minute to 400° C. and held for 1 hour. Final weight loss over 1 hour at 400° C. was 7.69% (FIG. 5).

The TGA scan (FIG. 5) clearly shows the initial weight loss previously observed with all polyimide samples, attributable to residual solvent loss or initial thermo-oxidative degradation of labile bonds in terminal groups. However, unlike polyimide Compound 2 Compound 1, with which weight loss stabilized within about 10 minutes and did not continue further over time (FIG. 2), polyimide Compound 7 steadily lost weight for an hour, evidencing thermo-oxidative breakdown of the polymer. This is consistent with rapid and substantial darkening during the long-term aging study in the oven at 250° C.

### Example 8: Comparison of Compounds 1, 5, and 6

Thin films (25 μm) of each compound (Compound 1, Compound 5, and Compound 6) in anisole were cast as described above and heat-cured.

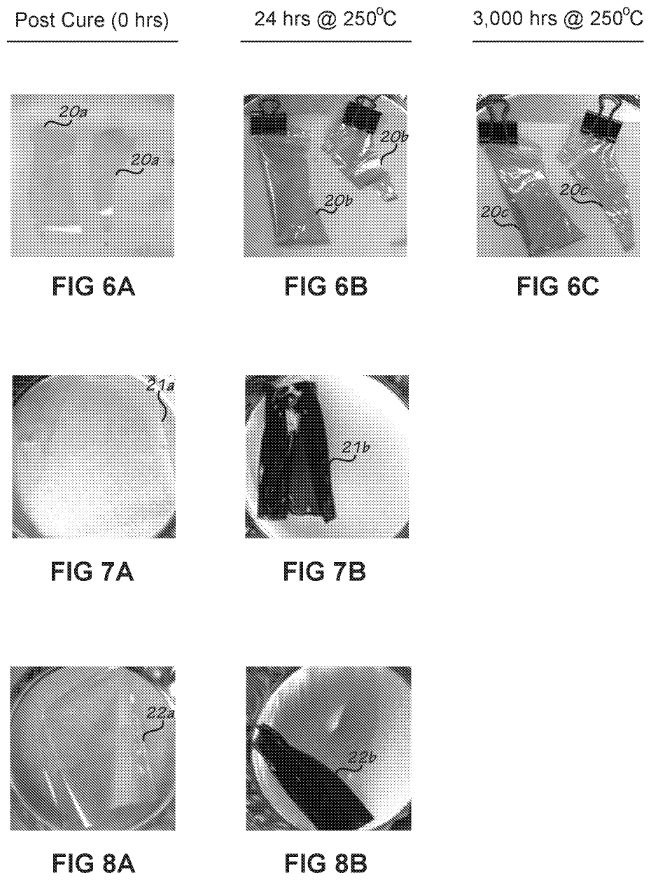

Samples of the films were thermally-aged at 250° C. for 24 hours, or 3,000 hours (Compound 1). Photographs of the films post-cure (no aging) and following thermal aging are shown in FIGS. 6A-2C (Compound 1); 7A-3B (Compound 6); and 8A-4B (Compound 5). Darkening of the film is an indication of thermal degradation and is not acceptable in material that will be exposed to high-temperature (≥250° C.) for prolonged lengths of time.

Each of the films was substantially transparent post cure (FIGS. 6A, 7A, and 8A). After 24 hours at 250° C., Compound 5 (˜10 mol %) and Compound 6 (˜15 mol %) were completely darkened and opaque indicating that up to 87% fluorination was insufficient to impart thermal stability. Compound 1 (98.16% fluorination) was only slightly darkened after 24 hours thermal aging, and this effect did not substantially increase after 4,000 hours at 250° C., indicating suitability for use in long duration high-temperature applications.

This data also indicates that even a small amount of an aliphatic group in the backbone of the polymer reduced thermo-oxidative stability of the material and led to the darkening of the product upon high temperature exposure.

A comparison of the composition and physical properties of Compound 1, Compound 5, and Compound 6 is summarized in Table 9, below.

TABLE 9
Synthetic Composition of Comparative Fluorinated Polyimides

| | Compound | | |
|---|---|---|---|
| | 1 | 5 | 6 |
| % Fluorinated compound | 98.16 | 87.42 | 82.03 |

Synthetic Composition of Compound (weight percent)

| | | | |
|---|---|---|---|
| Priamine ®-1075 | | 10.87 | 16.26 |
| F6-Diamine | 54.09 | 43.55 | 38.27 |
| 6-FDA | 44.07 | 43.88 | 43.77 |
| Phenol | 1.12 | 0.97 | 0.97 |
| Paraformaldehyde | 0.71 | 0.74 | 0.74 |
| Total | 100 | 100 | 100 |

TABLE 10
Properties of Comparative Fluorinated Polyimides

| | Compound | | |
|---|---|---|---|
| Properties | 1 | 5 | 6 |
| CTE, ppm/° C. | 32/57 | 46/251 | 69/104 |
| T_{g} (DMA) | 203.4 | 196.41 | 176.3 |
| Modulus @25° C. | 1.485 GPa | 1.65 GPa | 920 MPa |
| Dk | 2.4 | 2.5 | 2.55 |
| Df | 0.00380 | 0.00210 | 0.00158 |
| Td (5%), Air | 504 | 443 | 412.5 |
| Flammability | Yes | No | No |

### Example 9. Compositions: Effects of Fillers

To a glass beaker was added 35.0 g of a 20.0% solids solution Compound 1 in anisole (7 g of resin). To the beaker was added 3.0 g of fused silica (FB-5D, Denka, Tokyo JP). The mixture was thoroughly mixed with a spatula to make a slurry and was poured into an aluminum mold (127×127×0.5 mm) that was coated with a release agent. The slurry was degassed in a vacuum chamber to get rid of any air bubbles. The mold was placed in an oven at 100° C. for 5 hours to remove the anisole. The mold was then placed in an oven at 200° C. for 2 hours to cure the sample. The flexible cured film was removed from the mold and analyzed; the properties are listed in Table 11.

To a glass beaker was added 37.5 g of a 20.0% solids solution of Compound 1 in anisole (7.5 g of resin). To the beaker was added 2.5 g of PTFE powder (TF92072, 3M; Saint Paul, Minn.). The mixture was thoroughly mixed with a spatula to make a slurry and was poured into an aluminum mold (127×127×0.5 mm) that was coated with a release agent. The paste slurry was degassed in a vacuum chamber to get rid of any air bubbles. The mold was placed in an oven at 100° C. for 5 hours to remove the anisole. The mold was then placed in an oven at 200° C. for 2 hours to cure the sample. The flexible cured film was removed from the mold and analyzed; the properties are compared in Table 11, below.

TABLE 11
Effect of Fillers on Compound 1

| | Formulation | | |
|---|---|---|---|
| | Com- | 70% Compound 1 + | 75% Compound 1 + |
| Properties | pound 1 | 30% Silica Filler | 25% PTFE Filler |
| CTE, ppm/° C. | 32/57 | 27 | 38 |
| T_{g} (DMA) | 203.4 | 223 | 198 |
| Dk | 2.4 | 2.6 | 2.12 |
| Df | 0.00380 | 0.00370 | 0.00350 |
| Td (5%), Air | 504 | 529 | 504.9 |
| Flammability | UL94 V0 | UL94 V0 | UL94 V0 |

Table 11 shows that fillers can be added to the invention compounds to improve the properties of the composition, especially those important for making flexible copper clad laminates. PTFE significantly improved the Dk and Df values; however, the T_{g} and CTE suffered slightly. Fused silica improved the T_{g} and CTE, and the Df is slightly better than the resin itself, but the Dk does go up slightly from 2.4 to 2.6.

1-85. (canceled)

86. A thermo-oxidation-resistant composition comprising at least one compound having a structure according to the following Formula I: 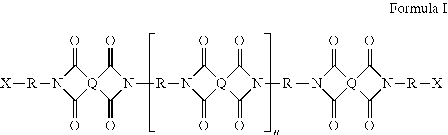
wherein,
R is selected from the group consisting of fluorinated aromatic, substituted aromatic, unsubstituted aromatic, and heteroaromatic moieties, and combinations thereof;
Q is selected from the group consisting of fluorinated aromatic, substituted aromatic, unsubstituted aromatic, and heteroaromatic moieties, and combinations thereof;
X is a curable moiety, optionally selected from the group consisting of benzoxazines, maleimides, citraconimides, itaconimide, and combinations thereof; and
n is 0 or an integer having the value from 1-100 or an integer having the value from 20-100;
with the proviso that no R or Q contains any primary, secondary, tertiary or benzylic hydrogen atoms; and
optionally comprising a solvent, wherein the solvent is optionally anisole.

87. The thermo-oxidation-resistant composition of claim 86, wherein the at least one compound is selected from the group consisting of: 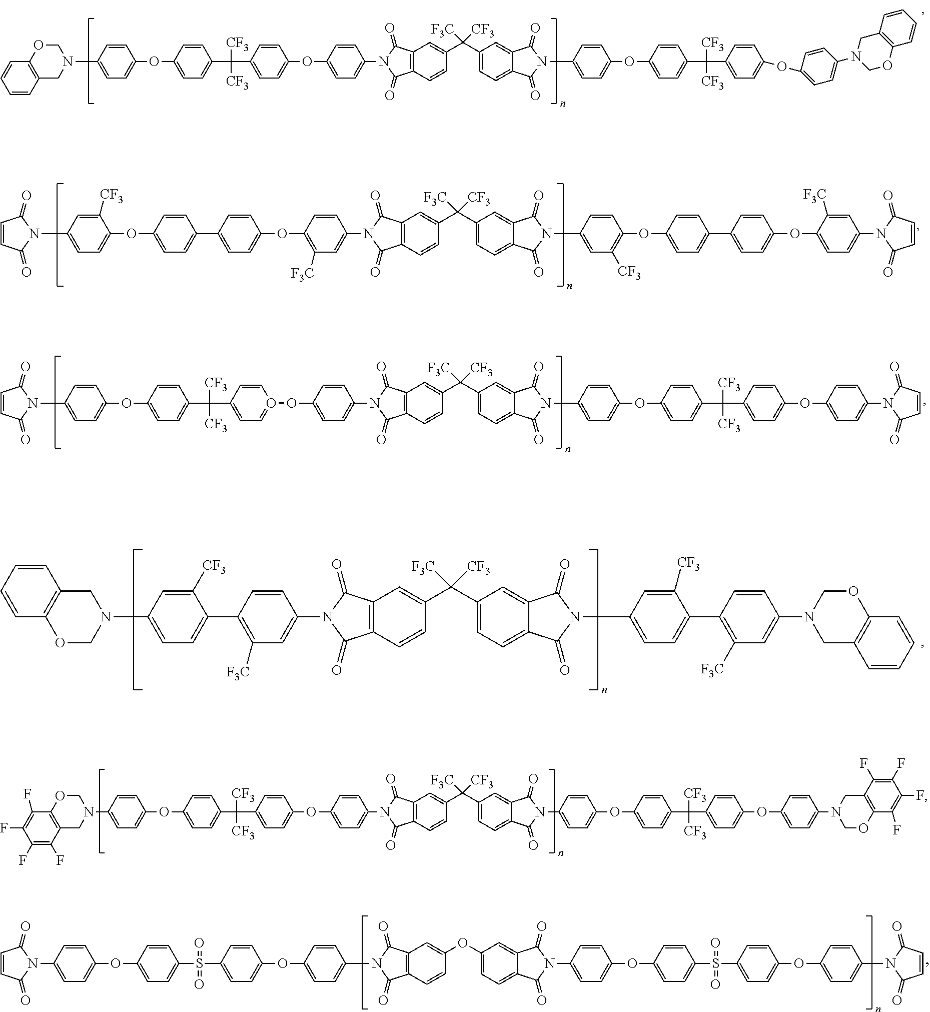 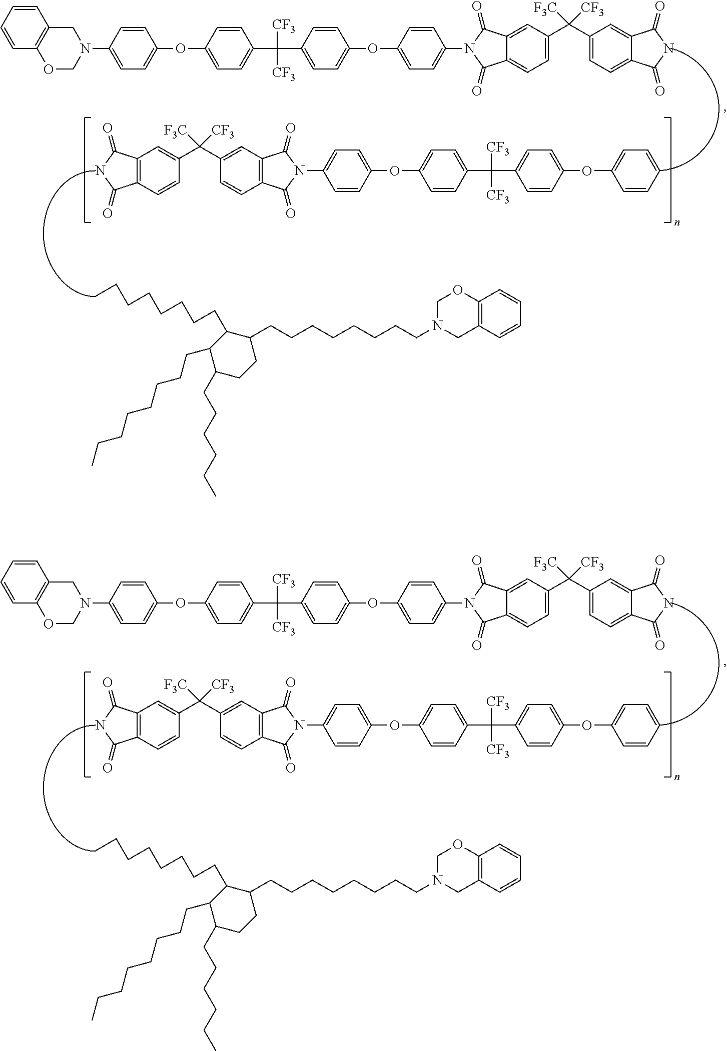 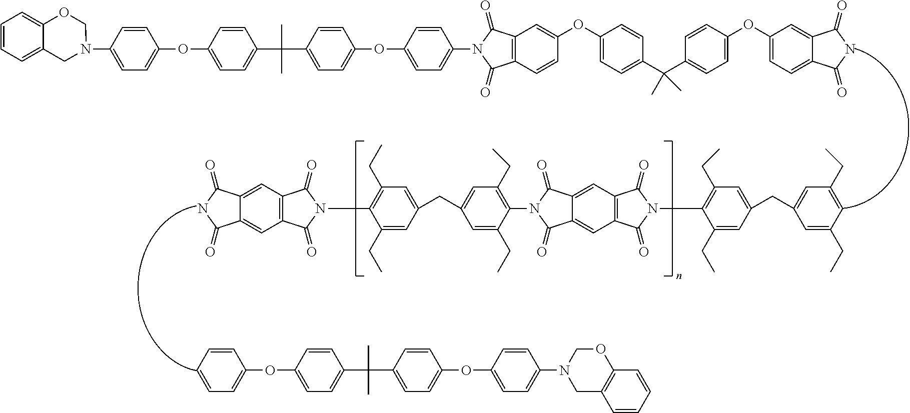
wherein n is an integer having the value from 1-100, and combinations thereof.

88. The thermo-oxidation-resistant composition of claim 86, further comprising at least one thermally stable filler, coupling agent, co-reactant, or a combination thereof, wherein:
a. optionally, the thermally stable filler, coupling agent, co-reactant, or combination thereof is stable to at least at 250° C. for at least 1,000 hours;
b. the thermally stable coupling agent is optionally selected from the group consisting of silane coupling agents, titanium coupling agents, zirconium coupling agents and combinations thereof;
c. the thermally stable filler is optionally selected from the group consisting of silica, perfluorinated hydrocarbons, graphite, carbon black, carbon nanotubes, POSS, boron nitride, silver, and copper alloys and combinations thereof; and
d. the thermally stable co-reactant is optionally selected from the group consisting of bismaleimides, benzoxazines, cyanate esters, allyl resins, vinyl ether resins, phenolic resins and combinations thereof.

89. The thermo-oxidation-resistant com or position of claim 86, wherein the composition is a coating, film, adhesive, or adhesive film.

90. The thermo-oxidation-resistant composition of claim 86, wherein the at least one compound is the product of a condensation of at least one diamine with at least one dianhydride.

91. The thermo-oxidation-resistant composition of claim 90, wherein the at least one diamine is selected from the group consisting of: 2,2-Bis[4-(4-aminophenoxy)phenyl] hexafluoropropane; 4,4-bis(4-amino-2-trifluoromethylphenoxy) biphenyl; 4,4′(Hexafluoroisopropylidene)bis[(4-aminophenoxy)benzene]; 4,4′-(Hexafluoroisopropylidene) dianiline; 3,3′-(Hexafluoroisopropylidene)dianiline; 4,4′-Diamino-2,2′-bis(trifluoromethyl)biphenyl; 1,4-Bis(4-amino-2-trifluoromethylphenoxy)benzene; 4,4′-Diaminooctafluorobiphenyl; 2,3,5,6-Tetrafluoro-1,4-phenylenediamine; 2,4,5,6-Tetrafluoro-1,3-phenylenediamine, bis(3-aminophenyl)sulfone; 1,4-bis(4-aminophenoxy)benzene; 4,4′-bis(4-aminophenoxy)biphenyl; bis[4-(4-aminophenoxy)phenyl]sulphone; 4,4′-diaminodiphenyl ether, and combinations thereof, or the at least one diamine has a structure selected from the group consisting of:

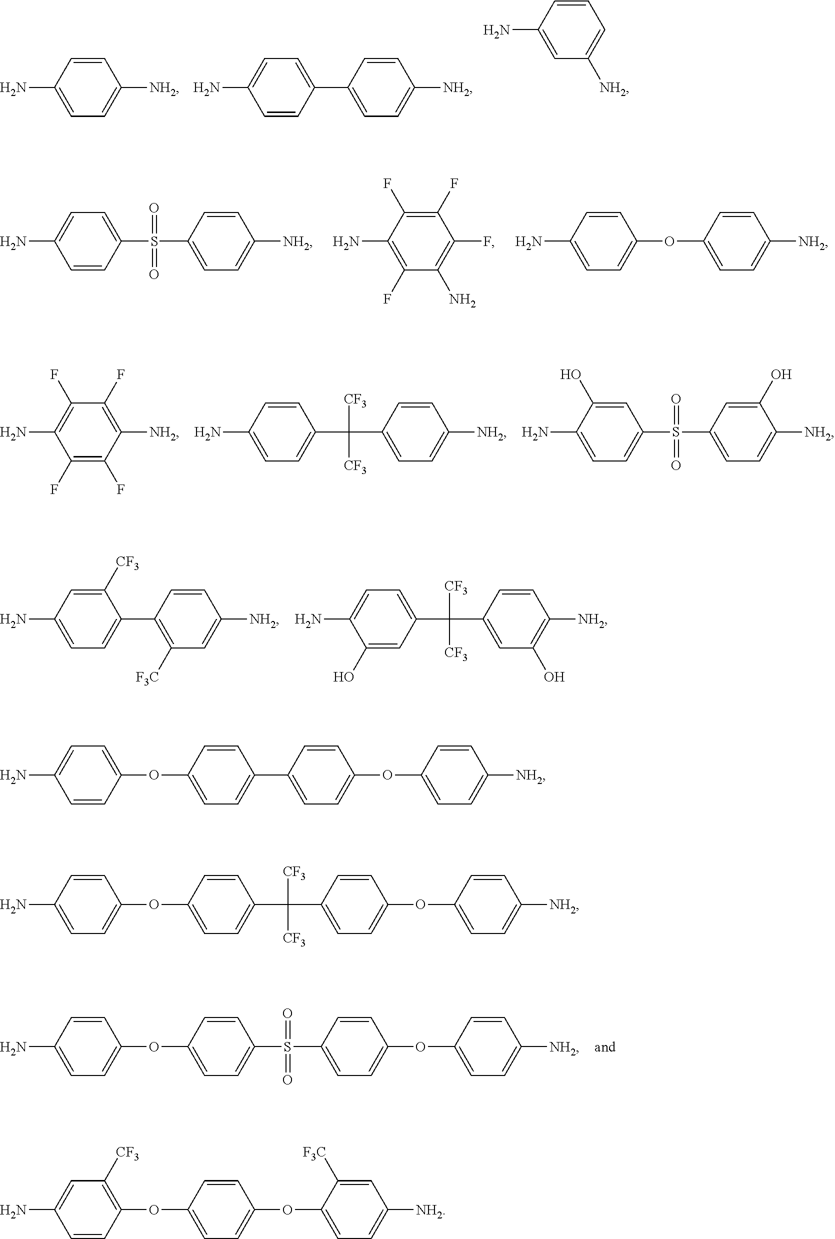

92. The thermo-oxidation-resistant composition of claim 90, wherein the at least one dianhydride is selected from the group consisting of 4,4′-(hexafluoroisopropylidene)diphthalic anhydride; pyromellitic dianhydride; diphenyl-3,3′,4,4′-tetracarboxylic dianhydride; 2,3,6,7-naphthalenetetracarboxylic 2,3,6,7-dianhydride; diphenyl-2,3,3′,4′-tetracarboxylic dianhydride, and combinations thereof, or the at least one dianhydride has a structure selected from the group consisting of:

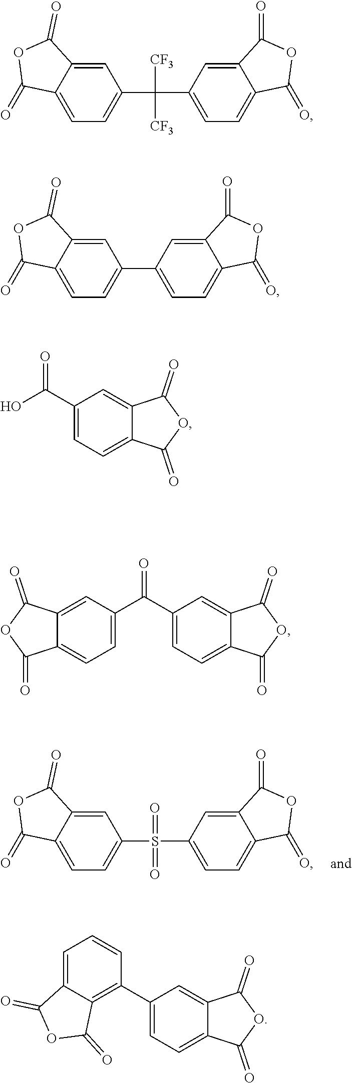

93. An assembly comprising at least one light emitting diode (LED) coated on at least one surface with a cured layer of the thermo-oxidation-resistant composition of claim 86, wherein optionally, the at least one LED is encapsulated in the cured layer of the thermo-oxidation-resistant composition.

94. A method for protecting an object from at least one environmental condition comprising the steps of:
a. coating the object on at least one surface or encapsulating the object on all sides with the thermo-oxidation-resistant coating of claim 89; and
b. curing the coating;
wherein, optionally, the at least one environmental condition is selected from the group consisting of an air, oxygen and oxidizing environment at a temperature above 250° C., which optionally further comprises at least one condition selected from the group consisting of dust, moisture, and UV light and combinations thereof.

95. The method of claim 94, wherein the object is an electronics element, that is optionally selected from a microelectronics element, a chip, a package, or a diode that is optionally a light emitting diode (LED).

96. The method of claim 94, wherein the object is under the hood or near the engine of a vehicle selected from the group consisting of: an automobile, a truck, a ship, a military vehicle, an airplane, and a space vehicle or any feature thereof.

97. A method for preparing a prepreg comprising the step of:
a. providing a reinforcing fiber, which is optionally a woven or unwoven fabric; and
b. immersing the reinforcing fiber in a liquid formulation of an uncured composition according to claim 86, thereby impregnating the reinforcing fiber; and optionally,
c. draining the prepreg to remove excess liquid formulation; and
d. drying the prepreg, o
thereby preparing a prepreg.

98. A prepreg prepared according to the method of claim 97.

99. A method for preparing a copper-clad laminate (CCL) comprising the steps of:
a. providing the prepreg of claim 98, and
b. disposing copper on one or both sides of the prepreg, wherein disposing optionally consists of electroplating copper to the one or the both sides of the prepreg or laminating copper foil to the one or the both sides of the prepreg;
thereby. preparing a copper-clad laminate.

100. A CCL comprising a reinforcing fiber impregnated with a thermo-oxidation-resistant composition according to claim 86 and having copper disposed on one or both sides.

101. A CCL prepared according to the method of claim 99.

102. A method for preparing a printed circuit board (PCB) comprising the steps of:
a. providing the CCL of claim 100;
b. etching circuit traces in the copper disposed on the one or the both sides of the CCL,
thereby preparing a printed circuit board.

103. A method for preparing a flexible copper clad laminate (FCCL) comprising the steps of:
a. providing the film of claim 89;
b. applying an adhesive to one of both sides of the film;
c. laminating copper foil to the adhesive on the one or the both sides of the film,
thereby preparing a FCCL.

104. A method for preparing a FCCL comprising the steps of:
a. providing the adhesive film of claim 89;
b. laminating copper foil to one or both sides of the film,
thereby preparing a flexible copper clad laminate.

105. An FCCL comprising the film of claim 89 having copper foil laminated to one or both sides of the film.
